(19) United States
(12) Patent Application Publication
(10) Pub. No.: US 2023/0145012 A1
(43) Pub. Date: May 11, 2023

(54) CLEANING LIQUID FOR SEMICONDUCTOR SUBSTRATE

(71) Applicant: FUJIFILM Corporation, Tokyo (JP)

(72) Inventor: Tetsuya KAMIMURA, Haibara-gun (JP)

(73) Assignee: FUJIFILM Corporation, Tokyo (JP)

(21) Appl. No.: 18/152,889

(22) Filed: Jan. 11, 2023

Related U.S. Application Data
(63) Continuation of application No. PCT/JP21/23811, filed on Jun. 23, 2021.

(30) Foreign Application Priority Data
Jul. 14, 2020 (JP) 2020-120677

(51) Int. Cl. C11D 1/62; C11D 3/20; C11D 3/30; C11D 1/42

(52) U.S. Cl. CPC C11D 1/62; C11D 3/2003; C11D 3/30; C11D 1/42

(57) ABSTRACT

There is provided a cleaning liquid for a semiconductor substrate, which has excellent cleaning performance with respect to a semiconductor substrate including a metal film after CMP and has a small surface roughness of a metal film after cleaning. The cleaning liquid for a semiconductor substrate according to the present invention is a cleaning liquid for a semiconductor substrate, which is used for cleaning a semiconductor substrate, including a compound represented by Formula (1), a compound represented by Formula (2), a primary amino alcohol having a primary amino group or a secondary amino group, a tertiary amine; and a solvent.

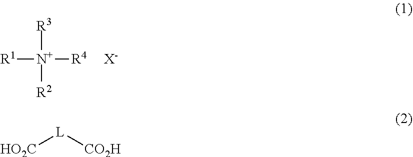

### CROSS-REFERENCE TO RELATED APPLICATIONS

This application is a Continuation of PCT International Application No. PCT/JP2021/023811 filed on Jun. 23, 2021, which claims priority under 35 U.S.C. § 119(a) to Japanese Patent Application No. 2020-120677 filed on Jul. 14, 2020. The above applications are hereby expressly incorporated by reference, in its entirety, into the present application.

### BACKGROUND OF THE INVENTION

### 1. Field of the Invention

The present invention relates to a cleaning liquid for a semiconductor substrate.

### 2. Description of the Related Art

Semiconductor elements such as charge-coupled devices (CCD) and memories are manufactured by forming fine electronic circuit patterns on a substrate, using photolithography technology. Specifically, semiconductor elements are manufactured by forming a resist film on a laminate that has a metal film serving as a wiring line material, an etching stop layer, and an interlayer insulating layer on a substrate, and carrying out a photolithography step and a dry etching step (for example, a plasma etching treatment).

In the manufacture of a semiconductor element, a chemical mechanical polishing (CMP) treatment in which a surface of a semiconductor substrate having a metal wiring line film, a barrier metal, an insulating film, or the like is flattened using a polishing slurry including polishing fine particles (for example, silica and alumina) may be performed. In the CMP treatment, polishing fine particles to be used in the CMP treatment, a polished wiring line metal film, and/or a metal component derived from a barrier metal and the like easily remain on a surface of a semiconductor substrate after CMP.

Since these residues can short-circuit wiring lines and affect the electrical characteristics of a semiconductor, a cleaning step in which these residues are removed from a surface of the semiconductor substrate is generally carried out.

For example, JP2010-174074A discloses a cleaning liquid for a copper wiring semiconductor, which contains a quaternary ammonium hydroxide, an amine, and water.

### SUMMARY OF THE INVENTION

In recent years, there has been a demand for further improvement in the cleaning performance of a cleaning liquid for a semiconductor substrate. Specifically, it ha been required that there are few residues on a metal film in a case where a metal film subjected to CMP is cleaned. Hereinafter, in the present specification, the fact that there are few residues on a metal film in a case where a metal film after CMP is cleaned is also referred to as that cleaning performance is excellent.

In addition, it has been required that the surface roughness of an obtained metal film is small in a case where the metal film is cleaned.

As a result of studying the cleaning liquid for a semiconductor substrate in the related art, the inventors of the present invention found that it is difficult to achieve excellent cleaning performance with respect to a semiconductor substrate including a metal film after CMP and achieve a small surface roughness of a metal film after cleaning.

An object of the present invention is to provide a cleaning liquid for a semiconductor substrate, which has excellent cleaning performance with respect to a semiconductor substrate including a metal film after CMP and has a small surface roughness of a metal film after cleaning.

The inventors of the present invention have found that the objects can be accomplished by the following configurations.

[1] A cleaning liquid for a semiconductor substrate, which is used for cleaning a semiconductor substrate, the cleaning liquid comprising:
a compound represented by Formula (1) described later;
a compound represented by Formula (2) described later;
a primary amino alcohol having a primary amino group or a secondary amino group;
a tertiary amine; and
a solvent.

[2] The cleaning liquid for a semiconductor substrate according to [1], in which at least one of R¹, . . . , or R⁴ in Formula (1) is a hydroxyalkyl group.

[3] The cleaning liquid for a semiconductor substrate according to [1] or [2], in which at least two of R¹, . . . , or R⁴ in Formula (1) is a hydroxyalkyl group.

[4] The cleaning liquid for a semiconductor substrate according to any one of [1] to [3], in which the compound represented by Formula (1) includes tris(2-hydroxyethyl)methylammonium hydroxide.

[5] The cleaning liquid for a semiconductor substrate according to any one of [1] to [4], in which a content of the compound represented by Formula (1) is 20.0% to 80.0% by mass with respect to a total mass of components of the cleaning liquid for a semiconductor substrate excluding the solvent.

[6] The cleaning liquid for a semiconductor substrate according to any one of [1] to [5], in which the tertiary amine is a secondary amino alcohol having a tertiary amino group.

[7] The cleaning liquid for a semiconductor substrate according to any one of [1] to [6], in which the tertiary amine includes 2-(dimethylamino)ethanol.

[8] The cleaning liquid for a semiconductor substrate according to any one of [1] to [7], in which a content of the tertiary amine is 3.0% to 35.0% by mass with respect to a total mass of components of the cleaning liquid for a semiconductor substrate excluding the solvent.

[9] The cleaning liquid for a semiconductor substrate according to any one of [1] to [8], in which a content of the compound represented by Formula (2) is 2.0% to 50.0% by mass with respect to a total mass of components of the cleaning liquid for a semiconductor substrate excluding the solvent.

[10] The cleaning liquid for a semiconductor substrate according to any one of [1] to [9], in which a mass ratio of a content of the compound represented by Formula (1) to a content of the tertiary amine is 1.00 to 30.00.

[11] The cleaning liquid for a semiconductor substrate according to any one of [1] to [10], in which a mass ratio of a content of the compound represented by Formula (1) to a content of the primary amino alcohol is 1.50 to 7.00.

[12] The cleaning liquid for a semiconductor substrate according to any one of [1] to [11], in which a mass ratio of a content of the tertiary amine to a content of the primary amino alcohol is 0.30 to 4.00.

[13] The cleaning liquid for a semiconductor substrate according to any one of [1] to [12], in which a ratio of the number of carbon atoms of the primary amino alcohol to the number of nitrogen atoms of the primary amino alcohol is 2 to 5.

[14] The cleaning liquid for a semiconductor substrate according to any one of [1] to [13], in which the primary amino alcohol includes at least two selected from the group consisting of an amino alcohol having a primary amino group and an amino alcohol having a secondary amino group.

[15] The cleaning liquid for a semiconductor substrate according to any one of [1] to [13], in which the primary amino alcohol includes at least one selected from the group consisting of 2-aminoethanol and 2-(2-aminoethylamino)ethanol.

[16] The cleaning liquid for a semiconductor substrate according to any one of [1] to [15], in which the primary amino alcohol includes 2-aminoethanol and 2-(2-aminoethylamino)ethanol.

[17] The cleaning liquid for a semiconductor substrate according to any one of [1] to [16], in which the primary amino alcohol includes 2-aminoethanol and 2-(2-aminoethylamino)ethanol, and

a mass ratio of a content of the 2-aminoethanol to a content of the 2-(2-aminoethylamino)ethanol is 0.50 to 900.00.

[18] The cleaning liquid for a semiconductor substrate according to any one of [1] to [17], in which the solvent includes water.

[19] The cleaning liquid for a semiconductor substrate according to any one of [1] to [18], in which a pH of the cleaning liquid for a semiconductor substrate is 8.0 to 13.0.

[20] The cleaning liquid for a semiconductor substrate according to any one of [1] to [19], in which the cleaning liquid for a semiconductor substrate is used for applying a cleaning liquid to a semiconductor substrate that has been subjected to a chemical mechanical polishing treatment to carry out cleaning.

According to the present invention, it is possible to provide a cleaning liquid for a semiconductor substrate, which has excellent cleaning performance with respect to a semiconductor substrate including a metal film after CMP and has a small surface roughness of a metal film after cleaning.

### DESCRIPTION OF THE PREFERRED EMBODIMENTS

Hereinafter, an example of a form for carrying out the present invention will be described.

In the present specification, a numerical value range expressed using “to” means a range that includes the preceding and succeeding numerical values of “to” as the lower limit value and the upper limit value, respectively.

In the present specification, in a case where two or more kinds of a certain component are present, the “content” of the component means the total content of the two or more kinds of the component.

In the present specification, “ppm” means “parts-per-million (10⁻⁶)”, and “ppb” means “parts-per-billion (10⁻⁹)”.

The compounds described in the present specification may include, unless otherwise limited, isomers (compounds having the same number of atoms but having different structures), optical isomers, and isotopes thereof. In addition, only one kind or a plurality of kinds of the isomers and the isotopes may be included.

In the present specification, psi is intended to be pound-force per square inch; 1 psi=6,894.76 Pa.

[Cleaning Liquid for Semiconductor Substrate]

A cleaning liquid for a semiconductor substrate (hereinafter, also referred to as a “cleaning liquid”) according to an embodiment of the present invention is a cleaning liquid that is used for cleaning a semiconductor substrate, where it contains a compound represented by Formula (1) described later (hereinafter, also referred to as a “compound (1)”), a compound represented by Formula (2) (hereinafter, also referred to as a “compound (2)”), a primary amino alcohol having a primary amino group or a secondary amino group (hereinafter, also simply referred to as a “primary amino alcohol”), a tertiary amine, and a solvent.

A mechanism by which the object of the present invention is solved is conceived to be that the coexistence of the compound (1), the compound (2), the primary amino alcohol, and the tertiary amine causes the respective components to act in a cooperative manner, whereby a desired effect is obtained.

Hereinafter, a case where at least one of an effect that cleaning performance with respect to a semiconductor substrate including a metal film after CMP is more excellent or an effect that the surface roughness of a metal film after cleaning is small is obtained, it is also referred to that the effect of the present invention is excellent.

Hereinafter, each component included in the cleaning liquid will be described.

[Compound represented by Formula (1)]

The cleaning liquid contains a compound represented by Formula (1) (a compound (1)).

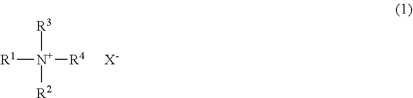

In Formula (1), R¹ to R⁴ each independently represent a hydrocarbon group which may have a substituent. However, a case where all of R¹ to R⁴ represent a methyl group is excluded.

The hydrocarbon group represented by R¹ to R⁴ may be linear, branched, or cyclic.

The hydrocarbon group represented by R¹ to R⁴ preferably has 1 to 20 carbon atoms, more preferably 1 to 10 carbon atoms, and still more preferably 1 to 8 carbon atoms.

Examples of the hydrocarbon group represented by R¹ to R⁴ include an aliphatic hydrocarbon group and an aromatic hydrocarbon group.

Examples of the hydrocarbon group represented by R¹ to R⁴ include an alkyl group, an alkenyl group, an alkynyl group, an aryl group, which may have a substituent, and a group obtained by combining these. Among them, the hydrocarbon group is preferably an alkyl group which may have a substituent.

Examples of the substituent contained in the hydrocarbon group include halogen atoms such as a fluorine atom, a chlorine atom, and a bromine atom; alkoxy groups such as a methoxy group, an ethoxy group, a propoxy group, an isopropyloxy group, a butoxy group, an isobutyloxy group, and a t-butyloxy group; hydroxy groups; alkoxycarbonyl groups such as a methoxycarbonyl group and an ethoxycarbonyl group; acyl groups such as an acetyl group, a propionyl group, and a benzoyl group; cyano groups; and nitro groups.

Among them, the substituent is preferably a hydroxy group.

Further, it is preferable that at R¹, . . . , or R⁴ is a hydrocarbon group having 2 or more carbon atoms, which may have a substituent, it is more preferable that at least two of R¹, . . . , or R⁴ is a hydrocarbon group having 2 or more carbon atoms, which may have a substituent, it is still more preferable that at least three of R¹ to R⁴ is a hydrocarbon group having 2 or more carbon atoms, which may have a substituent, and it is particularly preferable that three of R¹ to R⁴ is a hydrocarbon group having 2 or more carbon atoms, which may have a substituent. The upper limit of the number of carbon atoms thereof is not particularly limited; however, it is preferably 20 or less and more preferably 10 or less.

It is noted that the compound (1) does not include a case where all of R¹ to R⁴ represent a methyl group. That is, the compound (1) does not include, for example, a tetramethylammonium salt.

The alkyl group, the alkenyl group, and the alkynyl group, which are represented by R¹ to R⁴, may be linear, branched, or cyclic. In a case where the alkyl group, the alkenyl group, and the alkynyl group are cyclic, the ring may be monocyclic or polycyclic.

The alkyl group, the alkenyl group, and the alkynyl group preferably have 1 to 10 carbon atoms, more preferably 1 to 8 carbon atoms, still more preferably 1 to 5 carbon atoms, and particularly preferably 1 to 3 carbon atoms.

Examples of the substituent contained in the alkyl group, the alkenyl group, and the alkynyl group include the substituent contained in the hydrocarbon group represented by R¹ to R⁴ described above.

Among them, R¹ to R⁴ is preferably an alkyl group which may have a substituent, more preferably an unsubstituted alkyl group or a hydroxyalkyl group, still more preferably a methyl group, an ethyl group, a propyl group, a butyl group, or a 2-hydroxyethyl group, and particularly preferably a methyl group, an ethyl group, or a 2-hydroxyethyl group.

Further, it is preferable that at R¹, . . . , or R⁴ is an alkyl group which may have a substituent, it is more preferable that at R¹, . . . , or R⁴ is a hydroxyalkyl group (an alkyl group having a hydroxy group), it is still more preferable that at least two of R¹, . . . , or R⁴ is a hydroxyalkyl group, it is particularly preferable that at least three of R¹ to R⁴ is a hydroxyalkyl group, and it is most preferable that three of R¹ to R⁴ is a hydroxyalkyl group.

The aryl group represented by R¹ to R⁴ may be monocyclic or polycyclic.

The aryl group preferably has 5 to 20 carbon atoms, more preferably 6 to 15 carbon atoms, and still more preferably 6 to 10 carbon atoms.

The aryl group preferably has 1 to 5 rings, more preferably 1 to 3 rings, and still more preferably one ring.

Examples of the substituent contained in the aryl group include the substituent contained in the hydrocarbon group represented by R¹ to R⁴ described above.

Among them, examples of the aryl group represented by R¹ to R⁴ include a benzyl group, a phenyl group, a naphthyl group, an anthryl group, a phenanthryl group, an indenyl group, an acenaphthenyl group, a fluorenyl group, and a pyrenyl group. Among them, the aryl group is preferably a benzyl group, a phenyl group, or a naphthyl group, more preferably a benzyl group or a phenyl group, and still more preferably a benzyl group.

Further, it is preferable that 1 to 3 of R¹ to R⁴ are any aryl group which may have a substituent, it is more preferable that 1 to 2 of R¹ to R⁴ are an aryl group which may have a substituent, it is still more preferable that one of R¹ to R⁴ is an aryl group which may have a substituent, and it is particularly preferable that one of R¹ to R⁴ is a benzyl group.

X⁻ represents an anion. The kind of anion is not particularly limited. Examples thereof include various acid anions such as a carboxylate ion, a phosphate ion, a sulfate ion, a phosphonate ion, and a nitrate ion, hydroxide ions, and halide ions (for example, a chloride ion, a fluoride ion, and a bromide ion).

Examples of the compound (1) include trimethylethylammonium hydroxide (TMEAH), dimethyldiethylammonium hydroxide (DMDEAH), methyltriethylammonium hydroxide (MTEAH), tetraethylammonium hydroxide (TEAH), tetrapropylammonium hydroxide (TPAH), tetrabutylammonium hydroxide (TBAH), 2-hydroxyethyltrimethylammonium hydroxide (choline), bis(2-Hydroxyethyl)dimethylammonium hydroxide, tris(2-hydroxyethyl)methylammonium hydroxide, tetra(2-hydroxyethyl) ammonium hydroxide, benzyltrimethylammonium hydroxide (BTMAH), and cetyltrimethylammonium hydroxide.

Among them, from the viewpoint that the effect of the present invention is more excellent, the compound (1) is preferably tris(2-hydroxyethyl)methylammonium hydroxide, TEAH, choline, bis(2-hydroxyethyl)dimethylammonium hydroxide, TMEAH, or BTMAH, more preferably tris(2-hydroxyethyl)methylammonium hydroxide, choline, or bis(2-hydroxyethyl)dimethylammonium hydroxide, and still more preferably (2-hydroxyethyl)methylammonium hydroxide.

One kind of the compound (1) may be used alone, or two or more kinds thereof may be used.

The content of the compound (1) is preferably 20.0% to 80.0% by mass, more preferably 30.0% to 80.0% by mass, still more preferably 40.0% to 75.0% by mass with respect to the total mass of the components of the cleaning liquid excluding the solvent.

[Compound represented by Formula (2)]

The cleaning liquid contains a compound represented by Formula (2) (a compound (2)).

The compound (2) is a compound different from the organic acid described later.

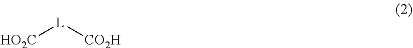

In Formula (2), L represents a single bond or a divalent linking group.

Examples of the divalent linking group represented by L include an ether group, a carbonyl group, an ester group, a thioether group, —SO₂—, —NT-(T is, for example, a substituent such as a hydrogen atom or an alkyl group), a divalent hydrocarbon group (for example, an alkylene group, an alkenylene group, an alkynylene, and an arylene group), and a group obtained by combining these.

In addition, the divalent linking group represented by L may further have a substituent. Examples of the substituent include an alkyl group, an aryl group, a hydroxy group, a carboxy group, an amino group, and a halogen atom.

Among them, the divalent linking group is preferably a single bond or a divalent hydrocarbon group, more preferably an alkylene group, and still more preferably a linear alkylene group.

The divalent linking group preferably has 1 to 15 carbon atoms, more preferably 1 to 10 carbon atoms, and still more preferably 1 to 5 carbon atoms.

Examples of the compound (2) include oxalic acid, malonic acid, succinic acid, glutaric acid, adipic acid, pimelic acid, sebacic acid, maleic acid, malic acid, citric acid, and tartaric acid.

Among them, from the viewpoint that the effect of the present invention is more excellent, the compound (2) preferably includes at least one selected from the group consisting of oxalic acid, succinic acid, malonic acid, glutaric acid, adipic acid, citric acid, and tartaric acid, more preferably includes at least one selected from the group consisting of succinic acid, malonic acid, glutaric acid, and adipic acid, and still more preferably includes succinic acid.

The molecular weight of the compound (2) is preferably 600 or less, more preferably 400 or less, and still more preferably 200 or less. The lower limit of the molecular weight is preferably 50 or more and more preferably 100 or more.

The compound (2) preferably has 20 or fewer carbon atoms, more preferably 15 or fewer carbon atoms, still more preferably 10 or few carbon atoms, and particularly preferably 5 or fewer carbon atoms. The lower limit of the number of carbon atoms is preferably 2 or more.

One kind of the compound (2) may be used alone, or two or more kinds thereof may be used.

In addition, the content of the compound (2) is preferably 1.0% to 50.0% by mass, more preferably 1.0% to 45.0% by mass, and still more preferably 3.0% to 35.0% by mass with respect to the total mass of the components of the cleaning liquid excluding the solvent.

The mass ratio of the content of the compound (1) to the content of the compound (2) [the content of the compound (1)/the content of the compound (2)] is preferably 0.10 to 50.00, more preferably 0.60 to 37.50, and still more preferably 1.00 to 30.00.

[Primary Amino Alcohol Having Primary Amino Group or Secondary Amino Group]

The cleaning liquid contains a primary amino alcohol having a primary amino group or a secondary amino group (the primary amino alcohol).

The primary amino alcohol is a compound having a primary amino group or a secondary amino group, and at least one hydroxy group (preferably a hydroxyalkyl group).

The primary amino alcohol is a compound different from each of the compound (1) described above and the tertiary amine described later.

The primary amino alcohol is not particularly limited as long as it is an amino alcohol having a primary amino group or a secondary amino group, and the primary amino alcohol may have a plurality of primary amino groups or a plurality of secondary amino groups.

The total number of primary amino groups and secondary amino groups contained in the primary amino alcohol is preferably 1 to 5, more preferably 1 to 3, and still more preferably 1 to 2.

It is noted that the primary amino alcohol does not have a tertiary amino group. In addition, in a case where the primary amino alcohol has both a primary amino group and a secondary amino group, it corresponds to a secondary amino alcohol. Specifically, 2-(2-aminoethylamino)ethanol corresponds to a secondary amino alcohol.

It suffices that the primary amino alcohol includes at least one selected from the group consisting of an amino alcohol having a primary amino group and an amino alcohol having a secondary amino group, where the primary amino alcohol preferably includes at least two selected from the group consisting of an amino alcohol having a primary amino group and an amino alcohol having a secondary amino group, and more preferably includes an amino alcohol having a primary amino group and an amino alcohol having a secondary amino group.

The number of hydroxy groups contained in the primary amino alcohol is preferably 1 to 5, more preferably 1 to 3, and still more preferably 1 to 2.

The primary amino alcohol preferably has 1 to 10 carbon atoms, more preferably 2 to 8 carbon atoms, and still more preferably 2 to 5 carbon atoms.

The primary amino alcohol preferably has 1 to 5 nitrogen atoms, more preferably 1 to 3 nitrogen atoms, and still more preferably 1 to 2 nitrogen atoms.

The ratio of the number of carbon atoms of the primary amino alcohol to the number of nitrogen atoms of the primary amino alcohol [the number of carbon atoms of the primary amino alcohol/the number of nitrogen atoms of the primary amino alcohol] is preferably 2 to 5, more preferably 2 to 4, and still more preferably 2 to 3. For example, in a case where the primary amino alcohol includes 2-aminoethanol, the number of carbon atoms is 2, the number of nitrogen atoms is 1, and thus the ratio of the number of carbon atoms to the number of nitrogen atoms is 2. In addition, as the numbers of carbon atoms and the number of nitrogen atoms, the respective total numbers of those of primary amino alcohols contained in the cleaning liquid are used in a case where the cleaning liquid according to the embodiment of the present invention contains two or more kinds of primary amino alcohols.

The primary amino alcohol is preferably a compound represented by Formula (X).

R^{x1}-L-OH Formula (X)

R^{x1} represents —NH₂ or —NHR^{x2}. R^{x2} represents an alkyl group which may have a primary amino group (—NH₂).

The alkyl group preferably has 1 to 5 carbon atoms and more preferably has 1 to 3 carbon atoms.

L represents an alkylene group. The alkylene group preferably has 1 to 5 carbon atoms.

The alkyl group represented by R^{x2} and the alkylene group represented by L may be linear or branched.

Examples of the primary amino alcohol include amino alcohols having a primary amino group, such as 2-aminoethanol (MEA), 2-amino-2-methyl-1-propanol (AMP), diethylene glycolamine (DEGA), trishydroxymethylaminomethane, 2-(methylamino)-2-methyl-1-propanol (N-MAMP), and 2-(aminoethoxy)ethanol; and amino alcohols having a secondary amino group, such as diethanolamine (DEA), and 2-(2-aminoethylamino)ethanol (AAE).

Among them, from the viewpoint that the effect of the present invention is more excellent, the primary amino alcohol preferably includes at least one selected from the group consisting of 2-aminoethanol, 2-amino-2-methyl-1-propanol, trishydroxymethylaminomethane, 2-(aminoethoxy)ethanol, and 2-(2-aminoethylamino)ethanol, more preferably includes at least one selected from the group consisting of 2-aminoethanol, 2-amino-2-methyl-1-propanol, and 2-(2-aminoethylamino)ethanol, and still more preferably includes at least one selected from the group consisting of 2-aminoethanol and 2-(2-aminoethylamino)ethanol.

In a case where the primary amino alcohol includes two or more primary amino alcohols, it is preferable that the primary amino alcohol includes trishydroxymethylaminomethane and includes 2-aminoethanol or 2-amino-2-methyl-1-propanol or that it includes 2-(2-aminoethylamino)ethanol and includes 2-aminoethanol, 2-amino-2-methyl-1-propanol, or trishydroxymethylaminomethane, and it is more preferable that the primary amino alcohol includes 2-aminoethanol and 2-(2-aminoethylamino)ethanol.

One kind of primary amino alcohol may be used alone, or two or more kinds thereof may be used.

The content of the primary amino alcohol is preferably 1.0% to 50.0% by mass and more preferably 10.0% to 40.0% by mass with respect to the total mass of the components of the cleaning liquid for a semiconductor substrate excluding the solvent.

In addition, in a case where the primary amino alcohol includes 2-aminoethanol and 2-(2-aminoethylamino)ethanol, the mass ratio of the content of 2-aminoethanol to the content of 2-(2-aminoethylamino)ethanol [the content of 2-aminoethanol/the content of 2-(2-aminoethylamino)ethanol] is preferably 0.10 to 2000.00, more preferably 0.50 to 900.00, and still more preferably 1.00 to 100.00.

The mass ratio of the content of the compound (1) to the content of the primary amino alcohol [the content of the compound (1)/the content of the primary amino alcohol] is preferably 1.00 to 30.00, more preferably 1.00 to 10.00, and still more preferably 1.50 to 7.00.

[Tertiary Amine]

The cleaning liquid contains a tertiary amine.

The tertiary amine is a compound different from each of the compound (1) described above, the primary amino alcohol described above, and the azole compound described later.

The tertiary amine is a compound having at least a tertiary amino group (>N—) in the molecule.

Examples of the tertiary amine include a tertiary aliphatic amine, a tertiary aromatic amine, and a secondary amino alcohol having a tertiary amino group (hereinafter, also simply referred to as a “secondary amino alcohol”).

<Tertiary Aliphatic Amine>

Examples of the tertiary aliphatic amine include a tertiary amine that has a tertiary amino group in the molecule but does not have an aromatic ring.

Examples of the tertiary aliphatic amine include alkyl amines such as trimethylamine and triethylamine.

In addition, examples of the tertiary aliphatic amine include a tertiary alicyclic amine and a tertiary aliphatic amine.

(Tertiary Alicyclic Amine)

The tertiary alicyclic amine is not particularly limited as long as it is a tertiary amine having a non-aromatic heterocyclic ring in which at least one of the atoms constituting the ring is a nitrogen atom.

Examples of the tertiary alicyclic amine include a cyclic amidine compound and a piperazine compound.

—Cyclic Amidine—

The cyclic amidine compound is a compound having a heterocyclic ring including an amidine structure (>N—C═N—) in the ring.

The number of ring members of the heterocyclic ring contained in the cyclic amidine compound is not particularly limited; however, it is preferably 5 or 6, and more preferably 6.

Examples of the cyclic amidine compound include diazabicycloundecene (1,8-diazabicyclo[5.4.0]undec-7-ene: DBU), diazabicyclononene (1,5-diazabicyclo[4.3.0]non-5-ene: DBN), 3,4,6,7,8,9,10,11-octahydro-2H-pyrimid[1.2-a]azocine, 3,4,6,7,8,9-hexahydro-2H-pyrido[1.2-a]pyrimidine, 2,5,6,7-tetrahydro-3H-pyrrolo[1.2-a]imidazole, 3-ethyl-2,3,4,6,7,8,9,10-octahydropyrimid[1.2-a]azepine, and creatinine. Among them, the cyclic amidine compound is preferably DBU or DBN.

—Piperazine Compound—

The piperazine compound is a compound having a hetero-6-membered ring (a piperazine ring) in which the opposite —CH— group of a cyclohexane ring is replaced with a tertiary amino group (>N—).

Examples of the piperazine compound include 1-methylpiperazine, 1-ethylpiperazine, 1-propylpiperazine, 1-butylpiperazine, 1,4-dimethylpiperazine, 1-phenylpiperazine, 1-(2-hydroxyethyl)piperazine (HEP), N-(2-aminoethyl)piperazine (AEP), 1,4-bis(2-hydroxyethyl) piperazine (BHEP), 1,4-bis(2-aminoethyl) piperazine (BAEP), and 1,4-bis(3-aminopropyl) piperazine (BAPP).

Among them, the piperazine compound is preferably 1-methylpiperazine, HEP, AEP, BHEP, BAEP, or BAPP.

Other examples of the tertiary alicyclic amine include a compound having a non-aromatic hetero-5-membered ring such as 1,3-dimethyl-2-imidazolidinone, and an aromatic compound having a 7-membered ring containing a nitrogen atom.

(Tertiary aliphatic amine) Examples of the tertiary aliphatic amine include an alkylene diamine such as 1,3-bis(dimethylamino)butane and a polyalkyl polyamine such as N,N,N′,N″,N″-pentamethyldiethylenetriamine.

The tertiary aliphatic amine preferably has one or more hydrophilic groups in addition to one tertiary amino group. Examples of the hydrophilic group include a carboxy group and a phosphate group.

The upper limit of the total number of the hydrophilic groups contained in the tertiary aliphatic amine is not particularly limited; however, it is preferably 4 or less, and more preferably 3 or less. The lower limit thereof is not particularly limited; however, it is preferably 1 or more.

The number of tertiary amino groups contained in the tertiary aliphatic amine is not particularly limited; however, it is preferably 1 to 4 and more preferably 1 to 3.

In addition, the molecular weight of the tertiary aliphatic amine is not particularly limited; however, it is preferably 200 or less and more preferably 150 or less. The lower limit thereof is not particularly limited; however, it is preferably 60 or more.

[Secondary Amino Alcohol]

It is also preferable that the tertiary amine is a secondary amino alcohol. The secondary amino alcohol is a compound having a tertiary amino group and further having at least one hydroxy group in the molecule.

The secondary amino alcohol is preferably a compound represented by Formula (Y).

R^{Y1}-L^{Y}-OH Formula (Y)

R^{Y1} represents —N(R^{Y2})₂. R^{Y2} represents an alkyl group.

The alkyl group preferably has 1 to 5 carbon atoms and more preferably has 1 to 3 carbon atoms.

L^{Y} represents an alkylene group. The alkylene group preferably has 1 to 5 carbon atoms.

The alkyl group represented by R^{Y2} and the alkylene group represented by L^{Y} may be linear or branched.

Examples of the secondary amino alcohol include triethanolamine (TEA), 2-(dimethylamino)ethanol, and 2-(dimethylamino)-2-methyl-1-propanol.

Among them, 2-(dimethylamino)ethanol or 2-(dimethylamino)-2-methyl-1-propanol is preferable, and 2-(dimethylamino)ethanol is more preferable.

The tertiary amine is preferably trimethylamine, 2-(dimethylamino)ethanol, or 2-(dimethylamino)-2-methyl-1-propanol, more preferably 2-(dimethylamino)ethanol or 2-(dimethylamino)-2-methyl-1-propanol, and still more preferably 2-(dimethylamino)ethanol

One kind of tertiary amine may be used alone, or two or more kinds thereof may be used.

In addition, the content of the tertiary amine is preferably 1.0% to 50.0% by mass, more preferably 3.0% to 45.0% by mass, and still more preferably 3.0% to 35.0% by mass with respect to the total mass of the components of the cleaning liquid excluding the solvent.

The mass ratio of the content of the compound (1) to the content of the tertiary amine[the content of the compound (1)/the content of the tertiary amine] is preferably 0.10 to 50.00, more preferably 0.50 to 38.00, and still more preferably 1.00 to 30.00.

The mass ratio of the content of the tertiary amine to the content of the primary amino alcohol [the content of the tertiary amine/the content of the primary amino alcohol] is preferably 0.01 to 10.00, more preferably 0.05 to 5.00, and still more preferably 0.30 to 4.00. The mass ratio of the content of the tertiary amine to the content of the compound (2) [the content of the tertiary amine/the content of the compound (2)] is preferably 0.01 to 50.00 and more preferably 0.50 to 15.00.

[Solvent]

The cleaning liquid contains a solvent.

Examples of the solvent include water and an organic solvent. Among these, water is preferable.

The kind of water used for the cleaning liquid is not particularly limited as long as it does not adversely affect a semiconductor substrate, and distilled water, deionized water, and pure water (ultrapure water) can be used. Pure water is preferable from the viewpoint that it includes almost no impurities and has less influence on a semiconductor substrate in a step of manufacturing the semiconductor substrate.

As the organic solvent, any one of the known organic solvents can be used, where a hydrophilic organic solvent such as an alcohol or a ketone is preferable.

One kind of solvent be used alone, or two or more kinds thereof may be used.

The content of the solvent in the cleaning liquid is preferably 1.0% by mass or more, more preferably 30.0% by mass or more, and still more preferably 60.0% by mass or more with respect to the total mass of the cleaning liquid. The upper limit value is not particularly limited, but is preferably 99.0% by mass or less, and more preferably 97.0% by mass or less with respect to the total mass of the cleaning liquid.

[Organic Acid]

The cleaning liquid may contain an organic acid.

The organic acid is a compound different from each of the compound (1), the compound (2), the primary amino alcohol, and tertiary amine, which are described above.

In addition, the organic acid is preferably a compound different from the components described later (a surfactant, an azole compound, a polyhydroxy compound having a molecular weight of 500 or more, and the like).

Examples of the acid group contained in the organic acid include a carboxy group, a phosphonate group, a sulfo group, and a phenolic hydroxyl group.

The organic acid that is used in the cleaning liquid preferably has at least one acid group selected from the group consisting of a carboxy group and a phosphonate group.

The organic acid preferably has a low molecular weight. Specifically, the molecular weight of the organic acid is preferably 600 or less and more preferably 450 or less. The lower limit of the molecular weight is not particularly limited; however, it is preferably 60 or more.

The organic acid preferably has 15 or fewer carbon atoms. The lower limit of the number of carbon atoms is not particularly limited; however, it is preferably 2 or more.

<Carboxylic Acid-Based Organic Acid>

The carboxylic acid-based organic acid is an organic acid having at least one (for example, 1 to 8) carboxy groups in the molecule.

The carboxylic acid-based organic acid is an organic acid having a carboxy group as a coordinating group in the molecule, and examples thereof include an amino polycarboxylic acid-based organic acid, an amino acid-based organic acid, and an aliphatic carboxylic acid-based organic acid.

Examples of the amino polycarboxylic acid-based organic acid include butylenediaminetetraacetic acid, diethylenetriaminepentacetic acid (DTPA), ethylenediaminetetrapropionic acid, triethylenetetraminehexacetic acid, 1,3-diamino-2-hydroxypropane-N,N,N′,N′-tetraacetic acid, propylenediaminetetraacetic acid, ethylenediaminetetrapropionic acid (EDTA), trans-1,2-diaminocyclohexanetetraacetic acid, ethylenediaminediacetic acid, ethylenediaminedipropionic acid, 1,6-hexamethylene-diamine-N,N,N′,N′-tetraacetic acid, N,N-bis(2-hydroxybenzyl)ethylenediamine-N,N-diacetic acid, diaminopropanetetraacetic acid, 1,4,7,10-tetraazacyclododecane-tetraacetic acid, diaminopropanoltetraacetic acid, (hydroxyethyl)ethylenediaminetriacetic acid, and iminodiacetic acid (IDA).

Among them, the amino polycarboxylic acid-based organic acid is preferably diethylenetriaminepentacetic acid (DTPA).

Examples of the amino acid-based organic acid include glycine, serine, α-alanine (2-aminopropionic acid), β-alanine (3-aminopropionic acid), lysine, leucine, isoleucine, cystine, cysteine, ethionine, threonine, tryptophan, tyrosine, valine, histidine, a histidine derivative, asparagine, aspartic acid, glutamine, glutamic acid, arginine, proline, methionine, phenylalanine, the compounds described in paragraphs [0021] to [0023] of JP2016-086094A, and salts thereof. It is noted that as the histidine derivative, the compounds described in JP2015-165561A, JP2015-165562A, and the like can be used, the contents of which are incorporated herein by reference. In addition, examples of the salt include an alkali metal salt such as a sodium salt or a potassium salt, an ammonium salt, a carbonate, and acetate.

<Phosphoric Acid-Based Organic Acid>

The phosphonic acid-based organic acid is an organic acid having at least one phosphonate group in the molecule. It is noted that a case where the organic acid has a phosphonate group and a carboxy group is classified into a carboxylic acid-based organic acid.

Examples of the phosphonic acid-based organic acid include an aliphatic phosphonic acid-based organic acid and an amino phosphonic acid-based acid.

The aliphatic phosphonic acid-based organic acid may further have a hydroxy group in addition to the phosphonate group and the aliphatic group.

Examples of the phosphonic acid-based organic acid include ethylidene diphosphonic acid, 1-hydroxyethylidene-1,1′-diphosphonic acid (HEDPO), 1-hydroxypropyridene-1,1′-diphosphonic acid, and 1-hydroxybutylidene-1,1′-diphosphonic acid, ethylaminobis(methylenephosphonic acid), dodecylaminobis(methylenephosphonic acid), nitrilotris(methylenephosphonic acid) (NTPO), ethylenediaminebis(methylenephosphonic acid) (EDDPO), 1,3-propylenediaminebis(methylenephosphonic acid), ethylenediaminetetra(methylenephosphonic acid) (EDTPO), ethylenediaminetetra(ethylenephosphonic acid), 1,3-propylenediaminetetra(methylenephosphonic acid) (PDTMP), 1,2-diaminopropanetetra(methylenephosphonic acid), 1,6-hexamethylenediaminetetra(methylenephosphonic acid), diethylenetriaminepenta(methylenephosphonic acid) (DEPPO), diethylenetriaminepenta(ethylenephosphonic acid), triethylenetetraminehexa(methylenephosphonic acid), and triethylenetetraminehexa(ethylenephosphonic acid). Among them, the phosphonic acid-based organic acid is preferably HEDPO.

The number of phosphonate groups contained in the phosphonic acid-based organic acid is preferably 2 to 5, more preferably 2 to 4, and still more preferably 2 or 3.

In addition, the phosphonic acid-based organic acid preferably has 12 or fewer carbon atoms, more preferably has 10 or fewer carbon atoms, and still more preferably 8 or fewer carbon atoms. The lower limit thereof is not particularly limited; however, it is preferably 1 or more.

As the phosphonic acid-based organic acid that is used in the cleaning liquid, not only the above-described compounds but also the compounds described in paragraphs [0026] to [0036] of WO2018/020878A and the compounds ((co)polymers) described in paragraphs [0031] to [0046] of WO2018/030006A can be used, the contents of which are incorporated herein by reference.

The phosphonic acid-based organic acid may be used alone or may be used in a combination of two or more kinds thereof.

In addition, the commercially available phosphonic acid-based organic acid may be a phosphonic acid-based organic acid containing water such as distilled water, deionized water, or ultrapure water in addition to the phosphonic acid-based organic acid.

In a case where the cleaning liquid contains a phosphonic acid-based organic acid, it is also preferable that the cleaning liquid further contains another acid (preferably, such a carboxylic acid-based organic acid as described above). In this case, the mass ratio of the content of the carboxylic acid-based organic acid to the content of the phosphonic acid-based organic acid [the content of the carboxylic acid-based organic acid/the content of the phosphonic acid-based organic acid] is preferably 0.1 to 10, more preferably 0.2 to 5, and still more preferably 0.6 to 1.3.

The organic acid is preferably one or more selected from the group consisting of an aliphatic carboxylic acid and an aliphatic phosphonic acid.

In addition, the organic acid is preferably one or more selected from the group consisting of DTPA, EDTA, trans-1,2-diaminocyclohexanetetraacetic acid, IDA, arginine, glycine, β-alanine, HEDPO, NTPO, EDTPO, and DEPPO, and it is more preferably one or more selected from the group consisting of DTPA and HEDPO.

One kind of organic acid may be used alone, or two or more kinds thereof may be used.

From the viewpoint that the performance of the cleaning liquid is excellent in a well-balanced, the content of the organic acid in the cleaning liquid is preferably 0.0005% to 25.0% by mass, more preferably 0.003% to 5.0%, and still more preferably 0.01 to 3.0% by mass with respect to the total mass of the components of the cleaning liquid excluding the solvent.

The mass ratio of the content of the organic acid to the content of the secondary amino alcohol [the content of the organic acid/the content of the secondary amino alcohol] is preferably 0.0001 to 10.0, more preferably 0.0010 to 1.5, still more preferably 0.0050 to 1.0, and particularly preferably 0.010 to 1.0.

[Surfactant]

The cleaning liquid may include a surfactant.

The surfactant is a component different from the components contained in the cleaning liquid described above (the compound (1), the compound (2), the primary amino alcohol, the tertiary amine, and the like).

The surfactant is preferably a compound having a hydrophilic group and a hydrophobic group (a lipophilic group) in one molecule. Examples of the surfactant include a nonionic surfactant, an anionic surfactant, a cationic surfactant, and an amphoteric surfactant.

Among them, the surfactant is preferably a nonionic surfactant.

In a large number of cases, the surfactant has a hydrophobic group selected from the group consisting of an aliphatic hydrocarbon group, an aromatic hydrocarbon group, and a group obtained by combining these. The hydrophobic group contained in the surfactant is not particularly limited, but in a case where the hydrophobic group includes an aromatic hydrocarbon group, the hydrophobic group preferably has 6 or more carbon atoms, and it more preferably has 10 or more carbon atoms. The upper limit of the number of carbon atoms of the hydrophobic group is not particularly limited; however, it is preferably 20 or less, and more preferably 18 or less.

In addition, in a case where the hydrophobic group does not include an aromatic hydrocarbon group and is composed only of an aliphatic hydrocarbon group, the hydrophobic group preferably has 9 or more carbon atoms, more preferably has 13 or more carbon atoms, and still more preferably has 16 or more carbon atoms. The upper limit of the number of carbon atoms of the hydrophobic group is not particularly limited; however, it is preferably 20 or less, and more preferably 18 or less.

(Nonionic Surfactant)

Examples of the nonionic surfactant include an ester-type nonionic surfactant, an ether-type nonionic surfactant, an ester-ether-type nonionic surfactant, and an alkanolamine-type nonionic surfactant.

Among them, an ether-type nonionic surfactant is preferable.

The nonionic surfactant preferably contains a group represented by Formula (A1).

-(LO)ₙ- Formula (A1)

In Formula (A1), L represents an alkylene group.

The alkylene group may be linear or branched. The alkylene group preferably has 1 to 10 carbon atoms, more preferably 2 or 3 carbon atoms, and still more preferably 2 carbon atoms.

n represents 3 to 60, and it is preferably 3 to 30, more preferably 6 to 20, and still more preferably 7 to 15. It is noted that n represents an integer value.

In other words, the group represented by Formula (A1) is a polyoxyalkylene group having a repetition number n (for example, a polyoxyethylene group, a polyoxypropylene group, or a polyoxyethylene polyoxypropylene group).

Among them, the group represented by Formula (A1) is preferably a polyoxyethylene group in which n is 3 to 30, more preferably a polyoxyethylene group in which n is 6 to 20, and still more preferably a polyoxyethylene group in which n is 7 to 15.

The group that is bonded to the terminal of the O side of the group represented by Formula (A1) (that is, the group that is bonded to the right side of the group represented by Formula (A1)) is preferably “*1-L-O-*2”. Lin “*1-L-O-*2” is the same as Lin Formula (A1), where *1 is a bonding position to O that is present at the terminal of the group represented by Formula (A1), and *2 is a bonding position on a side opposite to *1.

The group that is bonded to the terminal of the O side of the group represented by Formula (A1) (that is, the group that is bonded to the left side of the group represented by Formula (A1)) is preferably a hydrogen atom, an alkyl group, or an aromatic ring group which may have a substituent, and it is more preferably a hydrogen atom.

The alkyl group may be linear or branched. The alkyl group preferably has 1 to 30 carbon atoms.

The aromatic ring group preferably has 1 to 30 carbon atoms.

Examples of the substituent contained in the aromatic ring group include a hydrocarbon group (preferably having 1 to 30 carbon atoms) such as an alkyl group.

The group that is bonded to the terminal of the L side of the group represented by Formula (A1) is preferably a group other than “*3-O-L-O-*3”. Lin “*3-O-L-O-*3” is the same as L in Formula (A1), where *3 is a bonding position.

The group that is bonded to the terminal of the L side of the represented by Formula (A1) is preferably a hydroxyl group, an alkoxy group, or a group represented by aromatic ring-O—, which may have a substituent, and it is more preferably a group represented by aromatic ring-O—, which may have a substituent.

The alkoxy group may be linear or branched. The alkoxy group preferably has 1 to 30 carbon atoms, and it more preferably has 1 to 20 carbon atoms.

The aromatic ring group preferably has 1 to 30 carbon atoms, more preferably has 1 to 10 carbon atoms, and still more preferably has 3 to 6 carbon atoms.

In addition, examples of the substituent contained in the aromatic ring group include a hydrocarbon group (preferably having 1 to 30 carbon atoms) such as an alkyl group.

The nonionic surfactant more preferably contains a group represented by Formula (A2).

-Ph-O-(LO)ₙ- Formula (A2)

In Formula (A2), “(LO)ₙ” is the same as the group represented by Formula (A1).

In Formula (A2), Ph represents a phenylene group.

In the group represented by Formula (A2), the group that is bonded at the terminal on the Ph side is preferably a hydrogen atom or an alkyl group and more preferably an alkyl group.

The alkyl group may be linear or branched. The alkyl group preferably has 1 to 30 carbon atoms, more preferably 1 to 20 carbon atoms, and still more preferably 5 to 10 carbon atoms.

Examples of the nonionic surfactant include a compound represented by Formula (A).

R^{NA}-L^{NA1}-(LO)ₙ-L^{NA2}-H Formula (A)

In Formula (A), “(LO)ₙ” is the same as the group represented by Formula (A1).

In Formula (A), R^{NA} represents an alkyl group or an aryl group, which may have a substituent, or a group consisting of a combination thereof (an alkylaryl group (an aryl group substituted with an alkyl group) or the like).

Examples of the substituent include a halogen atom such as a fluorine atom and a hydroxyl group. The alkyl group may be linear or branched. The alkyl group preferably has 1 to 30 carbon atoms and more preferably 7 to 15 carbon atoms.

The aryl group preferably has 6 to 12 carbon atoms. One or more ethylene groups in the alkyl group may be replaced with a vinylene group.

In Formula (A), L^{NA1} and L^{NA2} each independently represent a single bond or a divalent linking group. The divalent linking group is preferably —O—, —CO—, —NR¹¹—, —S—, —SO₂—, —PO(OR¹²)—, an alkylene group which may have a substituent (preferably, having 1 to 6 carbon atoms), an arylene group which may have a substituent, or a group obtained by combining these groups. Here, R¹¹ represents a hydrogen atom, an alkyl group, an aryl group, or an aralkyl group. R¹² represents an alkyl group, an aryl group, or an aralkyl group.

Among them, L^{NA1} is preferably —O—. L^{NA2} is preferably a single bond.

Examples of the nonionic surfactant include polyoxyalkylene alkyl ethers (for example, polyoxyethylene stearyl ether), polyoxyalkylene alkenyl ethers (for example, polyoxyethylene oleyl ether), polyoxyethylene alkyl phenyl ethers (for example, polyoxyethylene nonyl phenyl ether), polyoxyalkylene glycol (for example, polyoxypropylene polyoxyethylene glycol), polyoxyalkylene monoalkylates (monoalkyl fatty acid ester polyoxyalkylene) (for example, polyoxyethylene monoalkylates such as polyoxyethylene monostearate and polyoxyethylene monooleate), polyoxyalkylene dialkylates (dialkyl fatty acid ester polyoxyalkylene) (for example, polyoxyethylene dialkylates such as polyoxyethylene distearate and polyoxyethylene diolate), bispolyoxyalkylene alkylamides (for example, bispolyoxyethylene stearylamide), a sorbitan fatty acid ester, a polyoxyethylene sorbitan fatty acid ester, a polyoxyethylene alkylamine, a glycerin fatty acid ester, an oxyethylene oxypropylene block copolymer, an acetylene glycol-based surfactant, and an acetylene-based polyoxyethylene oxide.

Among them, the nonionic surfactant is preferably a polyoxyethylene alkyl phenyl ether.

<Anionic Surfactant>

Examples of the anionic surfactant that can be used in the cleaning liquid include phosphoric acid ester-based surfactants having a phosphoric acid ester group, phosphonic acid-based surfactants having a phosphonate group, sulfonic acid-based surfactants having a sulfo group, carboxylic acid-based surfactants having a carboxy group, and sulfuric acid ester-based surfactants having a sulfuric acid ester group, respectively, as a hydrophilic group (acid group).

(Phosphoric Acid Ester-Based Surfactant)

Examples of the phosphoric acid ester-based surfactant include an alkyl phosphoric acid ester, and a polyoxyalkylene alkyl ether phosphoric acid ester, as well as a salt thereof. The phosphoric acid ester and the polyoxyalkylene alkyl ether phosphoric acid ester generally include both a monoester and a diester; however, the monoester or the diester can be used alone.

Examples of the salt of the phosphoric acid ester-based surfactant include a sodium salt, a potassium salt, an ammonium salt, and an organic amine salt.

The alkyl group contained in the alkylene phosphoric acid ester and the polyoxyalkylene alkyl ether phosphoric acid ester is not particularly limited; however, it is preferably an alkyl group having 2 to 24 carbon atoms, more preferably an alkyl group having 6 to 18 carbon atoms, and still more preferably an alkyl group having 12 to 18 carbon atoms.

The divalent alkylene group contained in the polyoxyalkylene alkyl ether phosphoric acid ester is not particularly limited; however, it is preferably an alkylene group having 2 to 6 carbon atoms, and more preferably an ethylene group or a 1,2-propanediyl group. In addition, the number of repetitions of the oxyalkylene group in the polyoxyalkylene ether phosphoric acid ester is preferably 1 to 12 and more preferably 1 to 6.

The phosphoric acid ester-based surfactant is preferably an octyl phosphoric acid ester, a lauryl phosphoric acid ester, a tridecyl phosphoric acid ester, a myristyl phosphoric acid ester, a cetyl phosphoric acid ester, a stearyl phosphoric acid ester, a polyoxyethylene octyl ether phosphoric acid ester, a polyoxyethylene lauryl ether phosphoric acid ester, a polyoxyethylene tridecyl ether phosphoric acid ester, or a polyoxyethylene myristyl ether phosphoric acid ester, more preferably a lauryl phosphoric acid ester, a tridecyl phosphoric acid ester, a myristyl phosphoric acid ester, a cetyl phosphoric acid ester, a stearyl phosphoric acid ester, or a polyoxyethylene myristyl ether phosphoric acid ester, and still more preferably, a lauryl phosphoric acid ester, a cetyl phosphoric acid ester, a stearyl phosphoric acid ester, or a polyoxyethylene myristyl ether phosphoric acid ester.

As the phosphoric acid ester-based surfactant, the compounds described in paragraphs [0012] to [0019] of JP2011-040502A can also be used, the contents of which are incorporated herein by reference.

(Phosphonic Acid-Based Surfactant)

Examples of the phosphonic acid-based surfactant include an alkylphosphonic acid, polyvinylphosphonic acid, and the aminomethylphosphonic acid described in JP2012-057108A or the like.

(Sulfonic Acid-Based Surfactant)

Examples of the sulfonic acid-based surfactant include alkyl sulfonic acid, alkyl benzene sulfonic acid, alkyl naphthalene sulfonic acid, alkyl diphenyl ether disulfonic acid, alkyl methyl taurine, sulfosuccinic acid diester, polyoxyalkylene alkyl ether sulfonic acid, and salts thereof.

The alkyl group contained in the sulfonic acid-based surfactant is not particularly limited; however, it is preferably an alkyl group having 2 to 24 carbon atoms and more preferably an alkyl group having 6 to 18 carbon atoms.

Moreover, the alkylene group contained in the polyoxyalkylene alkyl ether sulfonic acid is not particularly limited; however, it is preferably an ethylene group or a 1,2-propanediyl group. In addition, the number of repetitions of the oxyalkylene group in the polyoxyalkylene alkyl ether sulfonic acid is preferably 1 to 12, and more preferably 1 to 6.

Examples of the sulfonic acid-based surfactant include hexane sulfonic acid, octane sulfonic acid, decane sulfonic acid, dodecane sulfonic acid, toluene sulfonic acid, cumene sulfonic acid, octylbenzene sulfonic acid, dodecylbenzenesulfonic acid (DBSA), dinitrobenzene sulfonic acid (DNBSA), and lauryldodecylphenyl ether disulfonic acid (LDPEDSA). Among them, dodecanesulfonic acid, DBSA, DNBSA, or LDPEDSA is preferable, and DBSA, DNBSA, or LDPEDSA is more preferable.

(Carboxylic Acid-Based Surfactant)

Examples of the carboxylic acid-based surfactant include an alkylcarboxylic acid, an alkylbenzenecarboxylic acid, a polyoxyalkylene alkyl ether carboxylic acid, and salts thereof.

The alkyl group contained in the above-described carboxylic acid-based surfactant is not particularly limited; however, it is preferably an alkyl group having 7 to 25 carbon atoms, and more preferably an alkyl group having 11 to 17 carbon atoms.

Moreover, the alkylene group contained in the polyoxyalkylene alkyl ether carboxylic acid is not particularly limited; however, it is preferably an ethylene group or a 1,2-propanediyl group. In addition, the number of repetitions of the oxyalkylene group in the polyoxyalkylene alkyl ether carboxylic acid is preferably 1 to 12, and more preferably 1 to 6.

Examples of the carboxylic acid-based surfactant include lauric acid, myristic acid, palmitic acid, stearic acid, polyoxyethylene lauryl ether acetic acid, and polyoxyethylene tridecyl ether acetic acid.

(Sulfuric Acid Ester-Based Surfactant)

Examples of the sulfuric acid ester-based surfactant include a phosphoric acid ester (alkyl ether phosphoric acid ester), a polyoxyalkylene ether phosphoric acid ester, and salts thereof.

The alkyl group contained in the alkyl sulfuric acid ester and the polyoxyalkylene alkyl ether sulfuric acid ester is not particularly limited; however, it is preferably an alkyl group having 2 to 24 carbon atoms, and more preferably an alkyl group having 6 to 18 carbon atoms.

The alkylene group contained in the polyoxyalkylene alkyl ether sulfuric acid ester is not particularly limited; however, it is more preferably an ethylene group or a 1,2-propanediyl group. In addition, the number of repetitions of the oxyalkylene group in the polyoxyalkylene alkyl ether sulfuric acid ester is preferably 1 to 12, and more preferably 1 to 6.

Specific examples of the sulfuric acid ester-based surfactant include a lauryl sulfuric acid ester, a myristyl sulfuric acid ester, and a polyoxyethylene lauryl ether sulfuric acid ester.

As the surfactant, the compounds described in paragraphs [0092] to [0096] of JP2015-158662A, paragraphs [0045] and [0046] of JP2012-151273A, and paragraphs [0014] to [0020] of JP2009-147389A can also be used, the contents of which are incorporated herein by reference.

One kind of surfactant may be used alone, or two or more kinds thereof may be used.

In a case where the cleaning liquid contains a surfactant, from the viewpoint that the performance of the cleaning liquid is excellent in a well-balanced manner, the content of the surfactant is preferably 0.001% to 3.0% by mass, more preferably 0.01% to 1.0% by mass, and still more preferably 0.05% to 0.5% by mass with respect to the total mass of the components of the cleaning liquid excluding the solvent.

[Azole Compound]

The cleaning liquid may contain an azole compound.

The azole compound is a compound different from the components contained in the cleaning liquid described above.

The azole compound is an aromatic compound having a hetero-5-membered ring that contains at least one nitrogen atom.

The azole compound can improve the corrosion preventing action of the cleaning liquid. That is, the azole compound can act as an anticorrosion agent.

The number of nitrogen atoms contained in the hetero-5-membered ring of the azole compound is not particularly limited and is preferably 1 to 4, and more preferably 1 to 3.

In addition, all of these azole compounds may have substituents on the hetero-5-membered ring. Examples of the substituent include a hydroxy group, a carboxy group, a mercapto group, an amino group, an alkyl group having 1 to 4 carbon atoms, which may have an amino group, and a 2-imidazolyl group.

Examples of the azole compound include an imidazole compound in which one of the atoms constituting the azole ring is a nitrogen atom, a pyrazole compound in which two of the atoms constituting an azole ring are nitrogen atoms, and a thiazole compound in which one of the atoms constituting an azole ring is a nitrogen atom and the other is a sulfur atom, a triazole compound in which three of the atoms constituting an azole ring are nitrogen atoms, and a tetrazole compound in which four of the atoms constituting an azole ring are nitrogen atoms.

Examples of the imidazole compound include imidazole, 1-methylimidazole, 2-methylimidazole, 5-methylimidazole, 1,2-dimethylimidazole, 2-mercaptoimidazole, 4,5-dimethyl-2-mercaptoimidazole, 4-hydroxyimidazole, 2,2′-biimidazole, 4-imidazole carboxylic acid, histamine, benzoimidazole, and a purine base (adenine and the like).

Examples of the pyrazole compound include pyrazole, 4-pyrazolecarboxylic acid, 1-methylpyrazole, 3-methylpyrazole, 3-amino-5-methylpyrazole, 3-amino-5-hydroxypyrazole, 3-aminopyrazole, and 4-aminopyrazole.

Examples of the thiazole compound include 2,4-dimethylthiazole, benzothiazole, and 2-mercaptobenzothiazole.

Examples of the triazole compound include 1,2,4-triazole, 3-methyl-1,2,4-triazole, 3-amino-1,2,4-triazole, 1,2,3-triazole, 1-methyl-1,2,3-triazole, benzotriazole, 1-hydroxybenzotriazole, 1-dihydroxypropylbenzotriazole, 2,3-dicarboxypropylbenzotriazole, 4-hydroxybenzotriazole, 4-carboxybenzotriazole, 5-methylbenzotriazole, and 2,2′-{[(5-methyl-1H-benzotriazole-1-yl)methyl]imino}diethanol.

Examples of the tetrazole compound include 1H-tetrazole (1,2,3,4-tetrazole), 5-methyl-1,2,3,4-tetrazole, 5-amino-1,2,3,4-tetrazole, 1,5-pentamethylenetetrazole, 1-phenyl-5-mercaptotetrazole, and 1-(2-dimethylaminoethyl)-5-mercaptotetrazole.

The azole compound is preferably an imidazole compound or a triazole compound, and it is more preferably 1,2,4-triazole.

One kind of azole compound may be used alone, or two or more kinds thereof may be used.

In a case where the cleaning liquid contains an azole compound, the content of the azole compound is preferably 0.01% to 10.0% by mass, more preferably 0.1% to 5.0% by mass, and still more preferably 0.3% to 3.0% by mass with respect to the total mass of the components of the cleaning liquid excluding the solvent.

[Polyhydroxy Compound Having Molecular Weight of 500 or More]

The cleaning liquid may include a polyhydroxy compound having a molecular weight of 500 or more.

The polyhydroxy compound is a component different from the above-described respective components.

The polyhydroxy compound is an organic compound having two or more (for example, 2 to 200) alcoholic hydroxyl groups in one molecule.

The molecular weight (weight-average molecular weight in a case of having a molecular weight distribution) of the polyhydroxy compound is 500 or more, and preferably 500 to 3,000.

Examples of the polyhydroxy compound include polyoxyalkylene glycols such as polyethylene glycol, polypropylene glycol, and polyoxyethylene polyoxypropylene glycol; oligosaccharides such as manninotriose, cellotriose, gentianose, raffinose, melezitose, cellotetrose, and stachyose; and polysaccharides such as starch, glycogen, cellulose, chitin, and chitosan, and hydrolysates thereof.

In addition, It is also preferable that the polyhydroxy compound is cyclodextrin.

Cyclodextrin is one kind of cyclic oligosaccharide having a cyclic structure in which a plurality of D-glucoses are bonded by a glucoside bond. A compound in which 5 or more (for example, 6 to 8) glucoses are bonded are known.

Examples of the cyclodextrin include α-cyclodextrin, β-cyclodextrin, and γ-cyclodextrin. Among them, γ-cyclodextrin is preferable.

One kind of the polyhydroxy compound may be used alone, or two or more kinds thereof may be used.

In a case where the cleaning liquid contains the polyhydroxy compound, the content of the polyhydroxy compound is preferably 0.01% to 10.0% by mass, more preferably 0.05% to 5.0% by mass, and still more preferably 0.1% to 3.0% by mass with respect to the total mass of the components of the cleaning liquid excluding the solvent.

[Reducing Sulfur Compound]

The cleaning liquid may contain a reducing sulfur compound.

The reducing sulfur compound is a component different from the above-described respective components.

The reducing sulfur compound can improve the corrosion preventing action of the cleaning liquid. That is, the reducing sulfur compound can act as an anticorrosion agent.

The reducing sulfur compound is a compound that has reducing properties and contains a sulfur atom. Examples of the reducing sulfur compound include mercaptosuccinic acid, dithiodiglycerol, bis(2,3-dihydroxypropylthio)ethylene, sodium 3-(2,3-dihydroxypropylthio)-2-methyl-propylsulfonate, 1-thioglycerol, sodium 3-mercapto-1-propanesulfonate, 2-mercaptoethanol, thioglycolic acid, and 3-mercapto-1-propanol.

Among those, a compound having an SH group (mercapto compound) is preferable, and 1-thioglycerol, sodium 3-mercapto-1-propanesulfonate, 2-mercaptoethanol, 3-mercapto-1-propanol, or thioglycolic acid is more preferable.

One kind of the reducing sulfur compound may be used alone, or two or more kinds thereof may be used.

In a case where the cleaning liquid contains a reducing sulfur compound, the content of the reducing sulfur compound is preferably 0.01% to 10.0% by mass, more preferably 0.05% to 5.0% by mass, and still more preferably 0.1% to 3.0% by mass with respect to the total mass of the components of the cleaning liquid excluding the solvent.

[Polymer]

The cleaning liquid may include a polymer.

The polymer is a component different from the above-described respective components.

The molecular weight (the weight-average molecular weight in a case of having a molecular weight distribution) of the polymer is preferably more than 600, more preferably 1,000 or more, still more preferably more than 1,000, and particularly preferably more than 3,000. The upper limit of the molecular weight is not particularly limited; however, it is preferably 1,500,000 or less and more preferably 100,000 or less.

Among those, in a case where the polymer is a water-soluble polymer which will be described below, the weight-average molecular weight of the water-soluble polymer is preferably 1,000 or more, more preferably 1,500 or more, and still more preferably 3,000 or more. The upper limit of the weight-average molecular weight of the water-soluble polymer is not particularly limited, and it is preferably 1,500,000 or less, more preferably 1,200,000 or less, still more preferably 1,000,000 or less, and particularly preferably 10,000 or less.

Furthermore, in the present specification, the “weight-average molecular weight” refers to a weight-average molecular weight in terms of polyethylene glycol measured by gel permeation chromatography (GPC).

The polymer preferably has a repeating unit having a carboxy group (a repeating unit derived from (meth)acrylic acid, or the like). The content of the repeating unit having a carboxy group is preferably 30% to 100% by mass, more preferably 70% to 100% by mass, and still more preferably 85% to 100% by mass with respect to the total mass of the polymer.

It is also preferable that the polymer is a water-soluble polymer.

It is noted that the “water-soluble polymer” is intended to be a compound having two or more repeating units linked in a linear or mesh form through a covalent bond, in which the mass of the polymer dissolved in 100 g of water at 20° C. is 0.1 g or more.

Examples of the water-soluble polymer include a polyacrylic acid, a polymethacrylic acid, a polymaleic acid, a polyvinylsulfonic acid, a polyallylsulfonic acid, a polystyrenesulfonic acid, and salts thereof; copolymers of monomers such as styrene, α-methylstyrene, and/or 4-methylstyrene and acid monomers such as a (meth)acrylic acid and/or a maleic acid, and salts thereof; polymers having repeating units having an aromatic hydrocarbon group obtained by fusing benzenesulfonic acid and/or naphthalenesulfonic acid, and the like with formalin; vinyl-based synthetic polymers such as polyvinyl alcohol, polyoxyethylene, polyvinylpyrrolidone, polyvinylpyridine, polyacrylamide, polyvinyl formamide, polyethyleneimine, polyvinyloxazoline, polyvinylimidazole, and polyallylamine; and modified products of natural polysaccharides such as hydroxyethyl cellulose, carboxymethyl cellulose, and processed starch.

The water-soluble polymer may be a homopolymer or a copolymer obtained by copolymerizing two or more kinds of monomers. Examples of the monomer include monomers selected from the group consisting of a monomer having a carboxy group, a monomer having a sulfonic acid group, a monomer having a hydroxy group, a monomer having a polyethylene oxide chain, a monomer having an amino group, and a monomer having a heterocyclic ring.

It is also preferable that the water-soluble polymer is a polymer consisting of only structural units derived from the monomers selected from the group. In a case where the polymer is composed of substantially only a structural unit derived from the monomer selected from the group, for example, the content of the structural unit derived from the monomer selected from the group is preferably 95% to 100% by mass and more preferably 99% to 100% by mass with respect to the total mass of the polymer used.

Examples of the polymer also include the water-soluble compounds described in paragraphs [0043] to [0047] of JP2016-171294A, the contents of which are incorporated herein by reference.

One kind of polymer may be used alone, or two or more kinds thereof may be used.

In a case where the cleaning liquid contains a polymer, the content of the polymer is preferably 0.01% to 10.0% by mass, more preferably 0.05% to 5.0% by mass, and still more preferably 0.1% to 3.0% by mass with respect to the total mass of the components of the cleaning liquid excluding the solvent.

In a case where the content of the polymer is within the range, the polymer can be appropriately adsorbed on a surface of a substrate to contribute to the improvement of the corrosion prevention performance of the cleaning liquid, and can also improve a balance between the viscosity and/or the cleaning performance of the cleaning liquid.

[Oxidizing Agent]

The cleaning liquid may include an oxidizing agent.

The oxidizing agent is a component different from the above-described respective components.

Examples of the oxidizing agent include a peroxide, a persulfide (for example, a monopersulfide or a dipersulfide), a percarbonate, or an acid thereof or a salt thereof.

Examples of the oxidizing agent include an oxidative halide (a periodic acid such as iodic acid, metaperiodic acid, or orthoperiodic acid, a salts thereof, or the like), a perboric acid, a perboric acid salt, a cerium compound, a ferricyanide (potassium ferricyanide or the like).

In a case where the cleaning liquid contains an oxidizing agent, the content of the oxidizing agent is preferably 0.01% to 10.0% by mass, more preferably 0.05% to 5.0% by mass, and still more preferably 0.1% to 3.0% by mass with respect to the total mass of the components of the cleaning liquid excluding the solvent.

[pH Adjusting Agent]

The cleaning liquid may include a pH adjusting agent to adjust and maintain the pH of the cleaning liquid.

Examples of the pH adjusting agent include a basic compound and an acidic compound other than the components.

The pH adjusting agent is intended to be a component different from each of the above-described components. However, it is permissible to adjust the pH of the cleaning liquid by adjusting the adding amount of each of the above-described components.

Examples of the basic compound include a basic organic compound and a basic inorganic compound.

The basic organic compound is a basic organic compound different from the components contained in the cleaning liquid described above. Examples of the basic organic compound include amine oxides, nitro compounds, nitroso compounds, oximes, ketooximes, aldoximes, lactams, isocyanides, and urea.

Examples of the basic inorganic compound include an alkali metal hydroxide, an alkaline earth metal hydroxide, and ammonia.

Examples of the alkali metal hydroxide include lithium hydroxide, sodium hydroxide, potassium hydroxide, and cesium hydroxide. Examples of the alkaline earth metal hydroxide include calcium hydroxide, strontium hydroxide, and barium hydroxide.

Examples of the acidic compound include an inorganic acid.

Examples of the inorganic acid include hydrochloric acid, sulfuric acid, sulfurous acid, nitric acid, nitrite, phosphoric acid, boric acid, and hexafluorophosphoric acid. In addition, a salt of the inorganic acid may be used, and examples thereof include an ammonium salt of the inorganic acid, and more specifically, ammonium chloride, ammonium sulfate, ammonium sulfite, ammonium nitrate, ammonium nitrite, ammonium phosphate, ammonium borate, and ammonium hexafluoride phosphate.

As the acidic compound, a salt of the acidic compound may be used as long as it is an acid or an acid ion (anion) in an aqueous solution.

The pH adjusting agent may be used alone or may be used in a combination of two or more kinds thereof.

In a case where the cleaning liquid contains a pH adjusting agent, the content of the pH adjusting agent is selected according to kinds and amounts of other components, and the pH of a target cleaning liquid, and is preferably 0.01% to 3.0% by mass, and more preferably 0.05% to 1.0% by mass with respect to the total mass of the components of the cleaning liquid excluding the solvent.

The cleaning liquid may contain a fluorine compound and/or an organic solvent as a compound other than the above-described compound.

Examples of the fluorine compound include the compounds described in paragraphs [0013] to [0015] of JP2005-150236A, the contents of which are incorporated herein by reference.

The using amounts of the fluorine compound and organic solvent are not particularly limited and can be appropriately set as long as the effect of the present invention is not impaired.

The content of each of the components in the cleaning liquid is can be measured by a known method such as gas chromatography-mass spectrometry (GC-MS) or liquid chromatography-mass spectrometry (LC-MS), and ion-exchange chromatography (IC).

[Physical Properties of Cleaning Liquid]

<pH>

From the viewpoint that the performance of the cleaning liquid is excellent in a well-balanced manner, the pH of the cleaning liquid is preferably 8.0 to 14.0, more preferably 8.0 to 13.5, still more preferably 8.0 to 13.0, particularly preferably 8.5 to 13.0, and most preferably 9.0 to 12.5.

The pH of the cleaning liquid means the pH at the time of use of the cleaning liquid, and it means a pH of a diluted cleaning liquid in a case where the cleaning liquid is diluted to be used.

The pH of the cleaning liquid can be measured by a method based on JIS Z8802-1984, using a known pH meter. The measurement temperature of the pH is 25° C.

<Metal Content>

In the cleaning liquid, the content (measured as the ion concentration) of metals (metal elements of Fe, Co, Na, Cu, Mg, Mn, Li, Al, Cr, Ni, Zn, Sn, and Ag) contained as impurities in the liquid is preferably 5 ppm by mass or less, and more preferably 1 ppm by mass or less. In a view that high-purity cleaning liquids are further demanded in the manufacture of state-of-the-art semiconductor elements, the content of the metal is still more preferably a value of less than 1 ppm by mass, that is, a mass of ppb order or less, and particularly preferably 100 ppb by mass or less, and most preferably less than 10 ppb by mass. The lower limit thereof is not particularly limited; however, it is preferably 0.

Examples of a method for reducing the metal content include carrying out a purification treatment such as distillation and filtration using an ion exchange resin or a filter at a stage of raw materials used in the production of the cleaning liquid or a stage after the production of the cleaning liquid.

Other examples of the method for reducing the metal content include using a container with less elution of impurities, which will be described later as a container that accommodates the raw material or the produced cleaning liquid. In addition, other examples of the method include lining an inner wall of a pipe with a fluorine-based resin so that the metal component does not elute from the pipe and the like during the production of the cleaning liquid.

<Coarse Particle>

The cleaning liquid may include coarse particles, but the content of the cleaning liquid is preferably low. Here, the coarse particles mean particles having a diameter (particle diameter) of 0.4 μm or more in a case where the shape of the particles is regarded as a sphere.

As for the content of the coarse particles in the cleaning liquid, the content of the particles having a particle diameter of 0.4 m or more is preferably 1,000 or less, and more preferably 500 or less per 1 mL of the cleaning liquid. The lower limit thereof is not particularly limited; however, it may be 0. In addition, it is more preferable that the content of particles having a particle diameter of 0.4 m or more measured by the measuring method is no more than a detection limit.

The coarse particles contained in the cleaning liquid correspond to particles of dirt, dust, organic solids, inorganic solids, and the like contained as impurities in raw materials, and particles of dirt, dust, and organic solids, and inorganic solids brought in as contaminants during the preparation of the cleaning liquid, in which the particles are finally present as particles without being dissolved in the cleaning liquid.

The content of the coarse particles present in the cleaning liquid can be measured in a liquid phase by using a commercially available measuring device in a light scattering type liquid particle measuring method using a laser as a light source.

Examples of a method for removing the coarse particles include a purification treatment such as filtering which will be described later.

The cleaning liquid may be used in the form of a kit having raw materials of the cleaning liquid divided into a plurality of parts.

[Production of cleaning liquid]

The cleaning liquid can be produced by a known method. Hereinafter, a method for producing the cleaning liquid will be described in detail.

<Liquid Preparation Step>

The method for preparing a cleaning liquid is not particularly limited, and for example, a cleaning liquid can be produced by mixing the above-described respective components. The order and/or the timing of mixing the above-described respective components is not particularly limited, and for example, a production method in which the compound (1), the compound (2), the primary amino alcohol, and the tertiary amine are added sequentially to a container to which purified pure water has been incorporated, and then the mixture is stirred and mixed while a pH adjusting agent is added to the mixture to adjust the pH of the mixed solution, thereby carrying out the preparation, may be mentioned. In addition, in a case where water and the respective components are added to the container, they may be added all at once or dividedly a plurality of times.

A stirring device and a stirring method used for preparing a cleaning liquid are not particularly limited, and a known device as a stirrer or a disperser may be used. Examples of the stirrer include an industrial mixer, a portable stirrer, a mechanical stirrer, and a magnetic stirrer. Examples of the disperser include an industrial disperser, a homogenizer, an ultrasonic disperser, and bead mills.

The mixing of the respective components in the liquid preparation step for the cleaning liquid, and a purification treatment which will be described later, and the storage of the produced cleaning liquid are preferably carried out at a temperature of 40° C. or lower and more preferably at 30° C. or lower. The lower limit value of the storage temperature is not particularly limited; however, it is preferably 5° C. or higher, more preferably 10° C. or higher. In a case of preparing, treating, and/or storing the cleaning liquid in the temperature range, it is possible to maintain stable performance for a long period of time.

(Purification Treatment)

It is preferable to subject any one or more of the raw materials for preparing the cleaning liquid to a purification treatment in advance. The purification treatment is not particularly limited, and examples thereof include known methods such as distillation, ion exchange, and filtration.

The degree of purification is not particularly limited, but it is preferable to carry out the purification until the purity of the raw material is 99% by mass or more, and it is more preferable to carry out the purification until the purity of the stock solution is 99.9% by mass or more.

Specific examples of the method for the purification treatment include a method of passing a raw material through an ion exchange resin or a reverse osmosis membrane (RO membrane), and the like, a distillation of a raw material, and filtering which will be described later.

As the purification treatment, a plurality of the above-described purification methods may be combined and carried out. For example, the raw materials are subjected to primary purification by passing through an RO membrane, and then subjected to secondary purification by passing through a purification device consisting of a cation exchange resin, an anion exchange resin, or a mixed bed type ion exchange resin.

In addition, the purification treatment may be carried out a plurality of times.

(Filtering)

The filter that is used in filtering is not particularly limited as long as it is a filter that is used in a use application for filtering and the like in the related art. Examples thereof include a filter consisting of a fluororesin such as polytetrafluoroethylene (PTFE) and a tetrafluoroethylene-perfluoroalkyl vinyl ether copolymer (PFA), a polyamide-based resin such as nylon, and a polyolefin resin (including a high-density polyolefin and an ultrahigh-molecular-weight polyolefin) such as polyethylene and polypropylene (PP). Among these materials, a material selected from the group consisting of the polyethylene, the polypropylene (including a high-density polypropylene), the fluororesin (including PTFE and PFA), and the polyamide-based resin (including nylon) is preferable, and among these, the filter with the fluororesin is more preferable. In a case of carrying out filtering of the raw materials using a filter formed with these materials, it is possible to effectively remove high-polarity foreign matters which are likely to cause defects.

The critical surface tension of the filter is preferably 70 to 95 mN/m, and more preferably 75 to 85 mN/m. It is noted that the value of the critical surface tension of the filter is a nominal value of a manufacturer. In a case of using a filter having a critical surface tension in the range, it is possible to effectively remove high-polarity foreign matters which are likely to cause defects.

The pore diameter of the filter is preferably 2 to 20 nm, and more preferably 2 to 15 nm. By adjusting the pore diameter of the filter to be in the range, it is possible to reliably remove fine foreign matters such as impurities and aggregates included in the raw materials while suppressing clogging in filtering. With regard to the pore diameters herein, reference can be made to nominal values of filter manufacturers.

Filtering may be carried out only once or twice or more. In a case where filtering is carried out twice or more, the filters used may be the same as or different from each other.

Moreover, the filtering is preferably carried out at room temperature (25° C.) or lower, more preferably carried out at 23° C. or lower, and still more preferably carried out at 20° C. or lower. In addition, the temperature is preferably 0° C. or higher, more preferably 5° C. or higher, and still more preferably 10° C. or higher. In a case of carrying out filtering in the temperature range, it is possible to reduce the amounts of particulate foreign matter and impurities dissolved in the raw material and efficiently remove the foreign matter and impurities.

(Container)

The cleaning liquid (including the aspect of the kit or a diluted cleaning liquid described later) can be filled in any container and stored, transported, and used as long as corrosiveness does not become a problem.

In the use application for a semiconductor, the container is preferably a container which has a high degree of cleanliness inside the container and in which the elution of impurities from an inner wall of an accommodating portion of the container into each liquid is suppressed.

Examples of such a container include various containers commercially available as a container for a semiconductor cleaning liquid, such as “Clean Bottle” series manufactured by AICELLO MILIM CHEMICAL Co., Ltd. and “Pure Bottle” manufactured by Kodama Plastics Co., Ltd., but the container is not limited thereto.

In addition, as the container for accommodating the cleaning liquid, a container in which a liquid contact portion with each liquid, such as an inner wall of the accommodating portion, is formed from a fluorine-based resin (perfluororesin) or a metal which has been subjected to rust prevention and metal elution prevention treatments is preferable.

The inner wall of the container is preferably formed from one or more resins selected from the group consisting of a polyethylene resin, a polypropylene resin, and a polyethylene-polypropylene resin, other resins, and a metal which has been subjected to rust prevention and metal elution prevention treatments, such as stainless steel, Hastelloy, Inconel, and Monel.

As such other resins, a fluorine-based resin (perfluororesin) is preferable. In this manner, by using a container having an inner wall formed of a fluorine-based resin, occurrence of a problem of elution of ethylene or propylene oligomers can be suppressed, as compared with a container having an inner wall formed of a polyethylene resin, a polypropylene resin, or a polyethylene-polypropylene resin.

Specific examples of such a container having an inner wall which is a fluorine-based resin include a FluoroPure PFA composite drum manufactured by Entegris Inc. In addition, the containers described on page 4 of JP1991-502677A (JP-H3-502677A), page 3 of WO2004/016526A, and pages 9 and 16 of WO99/46309A can also be used.

Moreover, for the inner wall of the container, quartz and an electropolished metal material (that is, a completely electropolished metal material) are also preferably used, in addition to the above-described fluorine-based resin.

The metal material that is used for producing the electropolished metal material is preferably a metal material which includes at least one selected from the group consisting of chromium and nickel, and has a total content of chromium and nickel of more than 25% by mass with respect to the total mass of the metal material, and examples thereof include stainless steel and a nickel-chromium alloy.

The total content of chromium and nickel in the metal material is more preferably 30% by mass or more with respect to the total mass of the metal material.

In addition, the upper limit value of the total content of Cr and Ni in the metal material is not particularly limited; however, it is preferably 90% by mass or less.

A method for electropolishing the metal material is not particularly limited, and a known method can be used. For example, the methods described in paragraphs [0011] to [0014] of JP2015-227501A, paragraphs [0036] to [0042] of JP2008-264929A, or the like can be used.

The inside of these containers is preferably cleaned before the cleaning liquid is filled.

For the liquid used for the cleaning, the amount of the metal impurities in the liquid is preferably reduced. The cleaning liquid may be bottled in a container such as a gallon bottle and a coated bottle after the production, and then may be transported and stored.

In order to prevent the change in the components in the cleaning liquid during the storage, the inside of the container may be replaced with inert gas (nitrogen, argon, or the like) with a purity of 99.99995% by volume or more. In particular, a gas having a low moisture content is preferable. In addition, during the transportation and the storage, the temperature may be controlled to a normal temperature in the range of −20° C. to 20° C. to prevent deterioration.

(Clean Room) It is preferable that the handling including production of the cleaning liquid, opening and cleaning of a container, and filling of the cleaning liquid, the treatment analysis, and the measurements are all carried out in a clean room. It is preferable that the clean room satisfies 14644-1 clean room standards. It is preferable that the clean room satisfies any one of International Organization for Standardization (ISO) Class 1, ISO Class 2, ISO Class 3, or ISO Class 4, it is more preferable that the clean room satisfies ISO Class 1 or ISO Class 2, and it is still more preferable that the clean room satisfies ISO Class 1.

<Diluting Step>

It is preferable that the above-described cleaning liquid is subjected to a diluting step of carrying out dilution with a diluent such as water and then used for cleaning the semiconductor substrate.

The dilution ratio of the cleaning liquid in the diluting step may be appropriately adjusted according to the kind and the content of each component, the semiconductor substrate as an object to be cleaned, and the like. However, the ratio (the dilution ratio) of the diluted cleaning liquid to the cleaning liquid before dilution is preferably 10 to 10,000, more preferably 20 to 3,000, and still more preferably 50 to 1,000 in terms of mass ratio or volume ratio (volume ratio at 23° C.).

In addition, the cleaning liquid is preferably diluted with water from the viewpoint that it has more excellent defect inhibition performance.

That is, it is also possible suitably put into practical use a cleaning liquid (a diluted cleaning liquid) containing each component with an amount obtained by dividing a suitable content of each component (excluding water) contained in the above-described cleaning liquid by a dilution ratio (for example, 100) in the above-described range.

The change in the pH before and after dilution (the difference between the pH of the cleaning liquid before dilution and the pH of the diluted cleaning liquid) is preferably 1.0 or less, more preferably 0.8 or less, and still more preferably 0.5 or less.

A specific method for the diluting step of diluting the cleaning liquid is not particularly limited, and it may be carried out according to the above-described liquid preparation step for the cleaning liquid. The stirring device and the stirring method used in the diluting step are also not particularly limited, and the known stirring device mentioned in the liquid preparation step for the cleaning liquid may be used to carry out the dilution.

It is preferable to subject the water that is used in the diluting step to a purification treatment in advance. In addition, it is preferable to subject a diluted cleaning liquid obtained in a diluting step to a purification treatment.

The purification treatment is not particularly limited, and examples thereof include an ion component reducing treatment using an ion exchange resin, an RO membrane, or the like, and foreign matter removal using filtering, described as the above-described purification treatment for the cleaning liquid, and it is preferable to carry out any one of the treatments.

[Use Application of Cleaning Liquid]

The cleaning liquid is preferably used in a cleaning step of cleaning a semiconductor substrate that has been subjected to a chemical mechanical polishing (CMP) treatment. In addition, the cleaning liquid can also be used for cleaning a semiconductor substrate in a process of manufacturing a semiconductor substrate. Furthermore, the cleaning liquid can also be used for a buffing treatment as described later.

As described above, for the cleaning of the semiconductor substrate, a diluted cleaning liquid obtained by diluting the cleaning liquid may be used.

[Object to be Cleaned]

Examples of an object to be cleaned by the cleaning liquid include a semiconductor substrate having a metal film.

It is noted that in a case where “on the semiconductor substrate” is described in the present specification, it encompasses, for example, front and back surfaces, a side surface, and the inside of a groove of the semiconductor substrate. In addition, the metal film on the semiconductor substrate encompasses not only a case where the metal film is directly on a surface of the semiconductor substrate but also a case where the metal film is present on the semiconductor substrate through another layer.

Examples of the metal included in the metal film include at least one metal M selected from the group consisting of copper (Cu), cobalt (Co), tungsten (W), titanium (Ti), tantalum (Ta), ruthenium (Ru), chromium (Cr), hafnium (Hf), osmium (Os), platinum (Pt), nickel (Ni), manganese (Mn), zirconium (Zr), molybdenum (Mo), lanthanum (La), and iridium (Ir).

The semiconductor substrate preferably has a metal film containing a metal M, more preferably has a metal film containing at least one metal selected from the group consisting of W, Co, Cu, Ti, Ta, and Ru, still more preferably has a metal film containing at least one metal selected from the group consisting of Cu, W, and Co, and particularly preferably a metal film having Cu.

The semiconductor substrate, which is an object to be cleaned by using the cleaning liquid, is not particularly limited, and examples thereof include a substrate having a metal wiring line film, a barrier metal, and an insulating film on a surface of a wafer constituting the semiconductor substrate.

Specific examples of the wafer constituting a semiconductor substrate include a wafer consisting of a silicon-based material, such as a silicon (Si) wafer, a silicon carbide (SiC) wafer, and a silicon-including resin-based wafer (glass epoxy wafer), a gallium phosphorus (GaP) wafer, a gallium arsenic (GaAs) wafer, and an indium phosphorus (InP) wafer.

The silicon wafer may be an n-type silicon wafer in which a silicon wafer is doped with a pentavalent atom (for example, phosphorus (P), arsenic (As), and antimony (Sb)), and a p-type silicon wafer in which a silicon wafer is doped with a trivalent atom (for example, boron (B) and gallium (Ga)). The silicon of the silicon wafer may be, for example, any one of amorphous silicon, single crystal silicon, polycrystalline silicon, and polysilicon.

Among those, the cleaning liquid is useful for a wafer consisting of a silicon-based material, such as a silicon wafer, a silicon carbide wafer, and a resin-based wafer including silicon (glass epoxy wafers).

The semiconductor substrate may have an insulating film on the wafer.

Specific examples of the insulating film include a silicon oxide film (for example, a silicon dioxide (SiO₂) film, a tetraethyl orthosilicate (Si(OC₂H₅)₄) film (TEOS film), a silicon nitride film (for example, silicon nitride (Si₃N₄), and silicon nitride carbide (SiNC)), and a low-dielectric-constant (Low-k) film (for example, a carbon-doped silicon oxide (SiOC) film and a silicon carbide (SiC) film).

The metal film included in the semiconductor substrate is preferably a metal film containing at least one metal selected from the group consisting of copper (Cu), tungsten (W), and cobalt (Co), for example, a film containing copper as a main component (a copper-containing film), a film containing tungsten as a main component (a tungsten-containing film), a film containing cobalt as a main component (a cobalt-containing film), or a metal film composed of an alloy including one or more selected from the group consisting of W and Co.

Among the above, the semiconductor substrate preferably has a film (a copper-containing film) containing copper as a main component.

Examples of the copper-containing film include a wiring line film consisting of only metal copper (copper wiring line film), and a wiring line film made of an alloy consisting of metal copper and another metal (copper alloy wiring line film).

Specific examples of the copper alloy wiring line film include a wiring line film made of an alloy consisting of one or more metals selected from aluminum (Al), titanium (Ti), chromium (Cr), manganese (Mn), tantalum (Ta), and tungsten (W), and copper. More specific examples of the copper alloy wiring line film include a copper-aluminum alloy wiring line film (CuAl alloy wiring line film), a copper-titanium alloy wiring line film (CuTi alloy wiring line film), a copper-chromium alloy wiring line film (CuCr alloy wiring line film), a copper-manganese alloy wiring line film (CuMn alloy wiring line film), a copper-tantalum alloy wiring line film (CuTa alloy wiring line film), and a copper-tungsten alloy wiring line film (CuW alloy wiring line film).

Examples of the tungsten-containing film (metal film containing tungsten as a main component) include a metal film consisting of only tungsten (tungsten metal film) and a metal film made of an alloy consisting of tungsten and another metal (tungsten alloy metal film).

Specific examples of the tungsten alloy metal film include a tungsten-titanium alloy metal film (WTi alloy metal film), and a tungsten-cobalt alloy metal film (WCo alloy metal film).

The tungsten-containing film is used, for example, as a barrier metal or a connection part between the via and the wire.

Examples of the cobalt-containing film (metal film containing cobalt as a main component) include a metal film consisting of only metal cobalt (cobalt metal film), and a metal film (cobalt alloy metal film) made of an alloy consisting of metal cobalt and another metal.

Specific examples of the cobalt alloy metal film include a metal film made of an alloy consisting of one or more metals selected from titanium (Ti), chromium (Cr), iron (Fe), nickel (Ni), molybdenum (Mo), palladium (Pd), tantalum (Ta), and tungsten (W), and cobalt. More specific examples of the cobalt alloy metal film include a cobalt-titanium alloy metal film (CoTi alloy metal film), a cobalt-chromium alloy metal film (CoCr alloy metal film), a cobalt-iron alloy metal film (CoFe alloy metal film), a cobalt-nickel alloy metal film (CoNi alloy metal film), a cobalt-molybdenum alloy metal film (CoMo alloy metal film), a cobalt-palladium alloy metal film (CoPd alloy metal film), a cobalt-tantalum alloy metal film (CoTa alloy metal film), and a cobalt-tungsten alloy metal film (CoW alloy metal film).

The cleaning liquid is useful for a substrate having a cobalt-containing film. Among the cobalt-containing films, the cobalt metal film is often used as a wiring line film, and the cobalt alloy metal film is often used as a barrier metal.

Further, the cleaning liquid may be preferably used for cleaning a substrate which has, on a wafer constituting a semiconductor substrate, at least a copper-containing wiring line film and a metal film (a cobalt barrier metal) that is composed of only metallic cobalt and is a barrier metal of the copper-containing wiring line film, where the copper-containing wiring line film is in contact with the cobalt barrier metal on the surface of the substrate.

Methods for forming the insulating film, the tungsten-containing film, and the cobalt-containing film on a wafer constituting the semiconductor substrate are not particularly limited as long as they is methods that are generally carried out in this field.

Examples of a method of forming an insulating film include a method in which a wafer constituting a semiconductor substrate is subjected to a heat treatment in the presence of an oxygen gas to form a silicon oxide film, and then a gas of silane and ammonia is introduced thereto to form a silicon nitride film by a chemical vapor deposition (CVD) method.

Examples of a method for forming the tungsten-containing film and the cobalt-containing film include a method in which a circuit is formed on a wafer having insulating film by a known method with as a resist or the like, and then a tungsten-containing film and a cobalt-containing film are formed by a method such as plating and a CVD method.

<CMP Treatment>

The CMP treatment is a treatment in which a surface of a substrate having a metal wiring line film, a barrier metal, and an insulating film is flattened by a combined action of a chemical action using a polishing slurry including polishing fine particles (abrasive grains) and mechanical polishing.

A surface of the semiconductor substrate that has been subjected to the CMP treatment may have impurities remaining thereon, such as abrasive grains (for example, silica and alumina) used in the CMP treatment, a polished metal wiring line film, and metal impurities (metal residue) derived from the barrier metal. In addition, organic residues derived from a CMP treatment liquid used in the CMP treatment may remain. For example, since these impurities may short-circuit the wiring lines and deteriorate the electrical characteristics of the semiconductor substrate, the semiconductor substrate that has been subjected to the CMP treatment is subjected to a cleaning treatment for removing these impurities from the surface.

Specific examples of the semiconductor substrate that has been subjected to the CMP treatment include the substrate that has been subjected to a CMP treatment, described in Vol. 84, No. 3, 2018; however, the present invention is not limited thereto.

<Buffing Treatment>

A surface of the semiconductor substrate, which is an object to be cleaned by using the cleaning liquid, may be subjected to a CMP treatment and then to a buffing treatment.

The buffing treatment is a treatment of reducing impurities on the surface of the semiconductor substrate using a polishing pad. Specifically, the surface of the semiconductor substrate that has been subjected to the CMP treatment is brought into contact with the polishing pad, and the semiconductor substrate and the polishing pad are relatively slid while supplying a composition for a buffing treatment to the contact portion. As a result, impurities on the surface of the semiconductor substrate are removed by a frictional force of the polishing pad and a chemical action of a composition for a buffing treatment.

As the composition for a buffing treatment, a known composition for a buffing treatment can be appropriately used depending on the kind of the semiconductor substrate, and the kind and the amount of the impurities to be removed. The component included in the composition for a buffing treatment is not particularly limited, and examples thereof include a water-soluble polymer such as polyvinyl alcohol, water as a dispersion medium, and an acid such as nitric acid.

In addition, in one embodiment of the buffing treatment, it is preferable that a semiconductor substrate is buffed using the cleaning liquid as the composition for a buffing treatment.

A polishing device, polishing conditions, and the like, which are used in the buffing treatment, can be appropriately selected from known devices and conditions according to the kind of the semiconductor substrate, the object to be removed, and the like. Examples of the buffing treatment include the treatments described in paragraphs [0085] to [0088] of WO2017/169539A, the contents of which are incorporated herein by reference.

[Method for Cleaning Semiconductor Substrate]

A method for cleaning a semiconductor substrate is not particularly limited as long as it includes a cleaning step of cleaning a semiconductor substrate that has been subjected to a CMP treatment, using the cleaning liquid. The method for cleaning a semiconductor substrate preferably includes a step of applying a diluted cleaning liquid obtained in a diluting step to the semiconductor substrate that has been subjected to a CMP treatment to carry out cleaning.

The cleaning step of cleaning the semiconductor substrate using the cleaning liquid is not particularly limited as long as it is a known method to be carried out on a semiconductor substrate that has been subjected to a CMP treatment, and cleaning in any one of the modes that are generally carried out in this field, such as scrub cleaning in which a cleaning member such as a brush is physically brought into contact with a surface of the semiconductor substrate while supplying a cleaning liquid to a semiconductor substrate, thereby removing residues; an immersion mode in which a semiconductor substrate is immersed in a cleaning liquid; a spinning (dropping) mode in which a cleaning liquid is dropped while rotating a semiconductor substrate; and a spray mode in which a cleaning liquid is sprayed, may be adopted as appropriate. In the immersion type cleaning, it is preferable to subject the cleaning liquid in which the semiconductor substrate is immersed to an ultrasonic treatment from the viewpoint that impurities remaining on the surface of the semiconductor substrate can be further reduced.

The cleaning step may be carried out only once or twice or more. In a case of carrying out cleaning two or more times, the same method may be repeated or different methods may be combined.

As the method for cleaning the semiconductor substrate, either a single-wafer method or a batch method may be adopted. The single-wafer method is generally a method of treating semiconductor substrates one by one, and the batch method is generally a method of treating a plurality of semiconductor substrates at the same time.

The temperature of the cleaning liquid that is used for cleaning a semiconductor substrate is not particularly limited as long as it is a temperature that is usually used in this field. Generally, the cleaning is carried out at room temperature (about 25° C.), but any temperature can be selected in order to improve the cleaning properties and suppress the damage resistance to a member. For example, the temperature of the cleaning liquid is preferably 10° C. to 60° C., and more preferably 15° C. to 50° C.

The cleaning time in the cleaning of the semiconductor substrate is not particularly limited; however, from the viewpoint of practical use, it is preferably 10 seconds to 2 minutes, more preferably 20 seconds to 1 minute 30 seconds, and still more preferably 30 seconds to 1 minute.

The supply amount (the supply rate) of the cleaning liquid in the cleaning step for the semiconductor substrate is not particularly limited; however, it is preferably 50 to 5,000 mL/min, and more preferably 500 to 2,000 mL/min.

In the cleaning of the semiconductor substrate, a mechanical stirring method may be used in order to further improve the cleaning ability of the cleaning liquid.

Examples of the mechanical stirring method include a method of circulating a cleaning liquid on a semiconductor substrate, a method of flowing or spraying a cleaning liquid on a semiconductor substrate, and a method of stirring a cleaning liquid with an ultrasonic or a megasonic.

After cleaning the semiconductor substrate, a step of rinsing and cleaning the semiconductor substrate with a solvent (hereinafter referred to as a “rinsing step”) may be carried out.

The rinsing step is preferably a step which is carried out continuously subsequently after the cleaning step for the semiconductor substrate and in which rinsing is carried out with a rinsing solvent (a rinsing liquid) over 5 seconds to 5 minutes. The rinsing step may be carried out using the above-described mechanical stirring method.

Examples of the rinsing liquid include water (preferably deionized (DI) water), methanol, ethanol, isopropyl alcohol, N-methylpyrrolidinone, γ-butyrolactone, dimethyl sulfoxide, ethyl lactate, and propylene glycol monomethyl ether acetate. In addition, an aqueous rinsing liquid having a pH of more than 8.0 (an aqueous ammonium hydroxide that has been diluted, or the like) may be used.

As a method of bringing the rinsing liquid into contact with the semiconductor substrate, the above-described method of bringing the cleaning liquid into contact with the semiconductor substrate can be similarly applied.

In addition, after the rinsing step, a drying step of drying the semiconductor substrate may be carried out.

Examples of the drying method include, but not limited to, a spin drying method, examples of the drying method include a spin drying method, a method of flowing a dry gas onto a semiconductor substrate, a method of heating a substrate by a heating means such as a hot plate and an infrared lamp, a Marangoni drying method, a Rotagoni drying method, an isopropyl alcohol (IPA) drying method, and any combinations thereof.

### EXAMPLES

Hereinbelow, the present invention will be described in more detail with reference to Examples. The materials, the amounts of the materials to be used, the proportions, and the like shown in the Examples below may be modified as appropriate as long as the modifications do not depart from the spirit of the present invention. Accordingly, the scope of the present invention should not be construed as being limited to Examples shown below.

In the following Examples, the pH of the cleaning liquid was measured at 25° C. using a pH meter (manufactured by HORIBA, Ltd., model “F-74”) in accordance with JIS Z8802-1984.

Furthermore, in the production of cleaning liquids of Examples and Comparative Examples, handling of the container, and preparation, filling, storage, and analytical measurement of the cleaning liquids, measurements were carried out in a clean room satisfying a level of ISO Class 2 or lower.

[Raw Material for Cleaning Liquid]

As raw materials for the cleaning liquid, the following components to be contained in the cleaning liquid were used.

It is noted that as various components used in Examples, those all classified into a semiconductor grade or a high-purity grade equivalent thereto were used.

[Compound (1)]
Tris: Tris(2-hydroxyethyl)methylammonium hydroxide
TEAH: Tetraethylammonium hydroxide
Choline: 2-hydroxyethyltrimethylammonium hydroxide
Bis: Bis(2-hydroxyethyl)dimethylammonium hydroxide

[Comparative Compound]
TMAH: Tetramethylammonium hydroxide

[Tertiary amine]
DMMEA: 2-(dimethylamino)ethanol
DMAMP: 2-(dimethylamino)-2-methyl-1-propanol
Trimethyl amine

[Compound (2)]
Succinic acid
Oxalic acid
Malonic acid
Glutamic acid
Adipic acid
Tartaric acid

[Primary Amino Alcohol]
MEA (D1): Monoethanolamine
AEE (D2): 2-(2-aminoethylamino)ethanol
AMP (D3): 2-amino-2-methyl-1-propanol

[pH Adjusting Agent and Water]

In the step of manufacturing the cleaning liquids in Examples and Comparative Examples, any one of potassium hydroxide (KOH) or sulfuric acid (H₂SO₄) as well as commercially available ultrapure water (manufactured by FUJIFILM Wako Pure Chemical Corporation) was used as the pH adjusting agent.

It is noted that the content of the pH adjusting agent (potassium hydroxide or sulfuric acid) was 2% by mass or less with respect to the total mass of the cleaning liquid in any one of the cleaning liquids of Examples or Comparative Examples.

[Another Component]
Nonionic X: Compound shown below

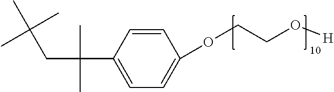

[Production of Cleaning Liquid]

Next, a method for producing the cleaning liquid will be described by taking Example 1 as an example.

Respective amounts of Tris, DMMEA, succinic acid, and MEA were added to ultrapure water so that the cleaning liquid to be finally obtained had the formulation shown in Table 1, and then a pH adjusting agent was added thereto so that the pH of the cleaning liquid to be prepared was 13.5. The obtained mixed solution was sufficiently stirred to obtain a cleaning liquid of Example 1.

According to the production method of Example 1, a cleaning liquid of each of Examples and Comparative Examples, having the composition shown in Table 1, was individually produced. The pH of the cleaning liquid of each of Examples or Comparative Examples was 13.5.

[Test]

[Evaluation of Cleaning Performance]

The cleaning performance (the residue removal performance) in a case where a metal film after CMP was cleaned was evaluated.

1 mL of the cleaning liquid of each Example and each Comparative Example was collected by separation and diluted 100-fold in terms of volume ratio with ultrapure water to prepare a sample of a diluted cleaning liquid.

A wafer (diameter: 12 inches) having a metal film consisting of copper on the surface was polished under the conditions in which a polishing pressure was set to 2.0 psi, a supply rate of the polishing liquid was set to 0.28 ml/(min·cm²), and a polishing time was set to 60 seconds, by using FREX300S-II (a polishing device, manufactured by Ebara Corporation).

BSL8180C (trade name, manufactured by FUJIFILM Electronic Materials Co., Ltd.) was used as a polishing liquid for polishing a wafer having a metal film consisting of copper.

Then, scrub cleaning was carried out for 60 minutes using the sample of each diluted cleaning liquid adjusted to room temperature (23° C.), and a drying treatment was carried out.

The number of defects on the polished surface of the obtained wafer was detected using a defect detection device, and each defect was observed with a scanning electron microscope (SEM) and subjected to defect classification. In a case of being necessary, the constitutional elements were analyzed by energy dispersion type X-ray analysis apparatus (EDAX) to specify the components. In this way, the number of defects based on the residues on the polished surface of the wafer was determined. Evaluation was carried out according to the following evaluation standards.

(Evaluation Standard)

A: The number of target defects is 200 or less.

B: The number of target defects is more than 200 and 300 or less.

C: The number of target defects is more than 300 and 400 or less.

D: The number of target defects is more than 400 and 500 or less.

E: The number of target defects is more than 500.

[Evaluation of Surface Roughness (Surface Smoothness)]

2 mL of the cleaning liquid of each Example or each Comparative Example was collected by separation and diluted 100-fold in terms of volume ratio with ultrapure water to prepare a sample of a diluted cleaning liquid.

A wafer (diameter: 12 inches) having a metal film consisting of tungsten on the surface was cut to prepare each 2 cm wafer coupon. The thickness of each metal film was set to 500 nm.

The wafer was immersed in the sample of the diluted cleaning liquid produced by the above-described method, and the surface roughness (Ra) of each metal film after 30 minutes was determined at room temperature (23° C.) and a stirring rotation speed of 250 rpm. The measurement region was evaluated at 4.0 m, and the evaluation was carried out using an AFM measuring instrument. Ra in the untreated state was 2.0 to 3.0 nm. Evaluation was carried out according to the following evaluation standards.

(Evaluation Standard)

A: Ra is 3.0 nm or less.

B: Ra is more than 3.0 nm and 3.5 nm or less.

C: Ra is more than 3.5 nm and 4.0 nm or less.

D: Ra is more than 4.0 nm and 4.5 nm or less.

E: Ra is more than 4.5 nm.

[Results]

The test results are shown in Table 1 below.

In the table, the column of “% by mass” shows the content (unit: % by mass) of each component with respect to the total mass of the cleaning liquid.

The column of “Concentration in solid content” shows the content (unit:% by mass) with respect to the total mass of the components of the cleaning liquid excluding the solvent.

The column of “(D) content” shows the content of the primary amino alcohol (the total content of D1 to D3 in the table).

The column of “(D1)” shows the MEA of the primary amino alcohol.

The column of “(D2)” shows the AEE of the primary amino alcohol.

The column of “(D3)” shows a primary amino alcohol other than MEA and AEE (other than D1 and D2).

The column of “(A)/(B)” shows the mass ratio of the content of the compound (1) to the content of the tertiary amine [the content of the compound (1)/the content of the tertiary amine].

The column of “(A)/(C)” shows the mass ratio of the content of the compound (1) to the content of the compound (2) [the content of the compound (1)/the content of the compound (2)].

The column of “(B)/(C)” shows the mass ratio of the content of the tertiary amine to the content of the compound (2) [the content of the tertiary amine/the content of the compound (2)].

The column of “(A)/(D)” shows the mass ratio of the content of the compound (1) to the content of the primary amino alcohol [the content of the compound (1)/the content of the primary amino alcohol].

The column of “(B)/(D)” shows the mass ratio of the content of the tertiary amine to the content of the primary amino alcohol [the content of the tertiary amine/the content of the primary amino alcohol].

The column of “(D1)/(D2)” shows the mass ratio of the content of MEA to the content of AEE [the content of MEEA/the content of AEE].

In the cleaning liquid, the remaining component (the remainder) that is neither a component specified as a component of the cleaning liquid in the table nor the pH adjusting agent is water.

TABLE 1

| | | | | | | | | | | (D) Primary |
|---|---|---|---|---|---|---|---|---|---|---|
| | (A) Compound (1) | | | (B) Tertiary amino | | | (C) Compound (2) | | | amino alcohol |
| | | | Concentration in | | | Concentration in | | | Concentration in | (D1) MEA |
| | Kind | Content | solid content | Kind | Content | solid content | Kind | Content | solid content | Kind |
| Example 1 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 2 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 3 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 4 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 5 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 6 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 7 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 8 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 9 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 10 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 11 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 12 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 13 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 14 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |
| Example 15 | [symbol] | [symbol] . [symbol] % | [symbol] . [symbol] % | [symbol] | [symbol] . [symbol] % | [symbol] . [symbol] % | Succinic | [symbol] . [symbol] % | [symbol] . [symbol] % | MEA |
| | | | | | | | acid | | | |

| | (D) Primary amino alcohol | | | | | | | | |
|---|---|---|---|---|---|---|---|---|---|
| | (D1) MEA | | (D2) AEE | | | (D1) Others | | | (D) Content |
| | | Concentration in | | | Concentration in | | | Concentration in | Concentration in |
| | Content | solid content | Kind | Content | solid content | Kind | Content | solid content | solid content |
| Example 1 | [symbol] . [symbol] % | [symbol] . [symbol] % | | | | | | | [symbol] . [symbol] % |
| Example 2 | [symbol] . [symbol] % | [symbol] . [symbol] % | | | | | | | [symbol] . [symbol] % |
| Example 3 | [symbol] . [symbol] % | [symbol] . [symbol] % | | | | | | | [symbol] . [symbol] % |
| Example 4 | [symbol] . [symbol] % | [symbol] . [symbol] % | | | | | | | [symbol] . [symbol] % |
| Example 5 | [symbol] . [symbol] % | [symbol] . [symbol] % | | | | | | | [symbol] . [symbol] % |
| Example 6 | [symbol] . [symbol] % | [symbol] . [symbol] % | | | | | | | [symbol] . [symbol] % |
| Example 7 | [symbol] . [symbol] % | [symbol] . [symbol] % | | | | | | | [symbol] . [symbol] % |
| Example 8 | [symbol] . [symbol] % | [symbol] . [symbol] % | | | | | | | [symbol] . [symbol] % |
| Example 9 | [symbol] . [symbol] % | [symbol] . [symbol] % | | | | | | | [symbol] . [symbol] % |
| Example 10 | [symbol] . [symbol] % | [symbol] . [symbol] % | | | | | | | [symbol] . [symbol] % |
| Example 11 | [symbol] . [symbol] % | [symbol] . [symbol] % | | | | | | | [symbol] . [symbol] % |
| Example 12 | [symbol] . [symbol] % | [symbol] . [symbol] % | | | | | | | [symbol] . [symbol] % |
| Example 13 | [symbol] . [symbol] % | [symbol] . [symbol] % | | | | | | | [symbol] . [symbol] % |
| Example 14 | [symbol] . [symbol] % | [symbol] . [symbol] % | | | | | | | [symbol] . [symbol] % |
| Example 15 | [symbol] . [symbol] % | [symbol] . [symbol] % | | | | | | | [symbol] . [symbol] % |

[symbol]

indicates data missing or illegible when filed

TABLE 2

| | Additive | | | | | | | | | | | | Evaluation | |
|---|---|---|---|---|---|---|---|---|---|---|---|---|---|---|
| | | | Concen- | | | | | | | | | | results | |
| (Continued | | | tration | | | | | | | pH | | pH | Cleaning | Surface |
| from | | | in solid | (A)/ | (A)/ | (B)/ | (A)/ | (B)/ | (D1)/ | adjusting | Water | after | perfor- | rough- |
| Table 1) | Kind | Content | content | (B) | (C) | (C) | (D) | (D) | (D2) | agent | Content | dilution | mance | ness |

| | | | | | | | | | | |
|---|---|---|---|---|---|---|---|---|---|---|
| Example 1 | 5.00 | 15.00 | 3.00 | 5.00 | 1.00 | H₂SO₄/KOH | Remainder | 12.1 | B | B |
| Example 2 | 5.00 | 15.00 | 3.00 | 5.00 | 1.00 | H₂SO₄/KOH | Remainder | 1 [symbol] . [symbol] | D | D |
| Example 3 | 5.00 | 15.00 | 3.00 | 5.00 | 1.00 | H₂SO₄/KOH | Remainder | 11.6 | C | C |
| Example 4 | 5.00 | 15.00 | 3.00 | 5.00 | 1.00 | H₂SO₄/KOH | Remainder | 12.2 | C | B |
| Example 5 | 1.00 | [symbol] .00 | 3.00 | 1.00 | 1.00 | H₂SO₄/KOH | Remainder | 11.4 | B | C |
| Example 6 | 1. [symbol] 7 | 5.00 | 3.00 | 1.67 | 1.00 | H₂SO₄/KOH | Remainder | 11.3 | B | B |
| Example 7 | 3.33 | 10.00 | 3.00 | 3.33 | 1.00 | H₂SO₄/KOH | Remainder | 11. [symbol] | B | B |
| Example 8 | 6.67 | 20.00 | 3.00 | 6.67 | 1.00 | H₂SO₄/KOH | Remainder | 11.1 | B | B |
| Example 9 | [symbol] . [symbol] | 25.00 | 3.00 | [symbol] .33 | 1.00 | H₂SO₄/KOH | Remainder | 12.2 | B | C |
| Example 10 | 5.00 | 15.00 | 3.00 | [symbol] .00 | 1.00 | H₂SO₄/KOH | Remainder | 12.3 | B | B |
| Example 11 | 5.00 | 15.00 | 3.00 | [symbol] .00 | 1.00 | H₂SO₄/KOH | Remainder | 12.1 | D | B |
| Example 12 | [symbol] 0.00 | 15.00 | 0.50 | [symbol] .00 | 0.17 | H₂SO₄/KOH | Remainder | 12.1 | C | B |
| Example 13 | 15.00 | 15.00 | 1.00 | [symbol] .00 | 0.33 | H₂SO₄/KOH | Remainder | 12.1 | B | B |
| Example 14 | 1.50 | 15.00 | 10.00 | 5.00 | [symbol] . [symbol] | H₂SO₄/KOH | Remainder | 12.1 | B | B |
| Example 15 | 1.00 | 15.00 | 15.00 | 5.00 | 5.00 | H₂SO₄/KOH | Remainder | 12. [symbol] | C | B |

[symbol]

indicates data missing or illegible when filed

TABLE 3

| | | | | | | | | | | (D) Primary |
|---|---|---|---|---|---|---|---|---|---|---|
| | (A) Compound (1) | | | (B) Tertiary amino | | | (C) Compound (2) | | | amino alcohol |
| | | | Concentration in | | | Concentration in | | | Concentration in | (D1) MEA |
| | Kind | Content | solid content | Kind | Content | solid content | Kind | Content | solid content | Kind |
| Example 16 | Tris | 1 [symbol] .0% | 6 [symbol] .8% | DMMEA | 3.0% | 14.0% | Succinic | 0.5% | 2.3% | MEA |
| | | | | | | | acid | | | |
| Example 17 | Tris | 1 [symbol] .0% | [symbol] 2.5% | DMMEA | 3.0% | 12.5% | Succinic | [symbol] .0% | 12.5% | MEA |
| | | | | | | | acid | | | |
| Example 18 | Tris | 1 [symbol] .0% | [symbol] 7.7% | DMMEA | 3.0% | 11.5% | Succinic | [symbol] .0% | 19.2% | MEA |
| | | | | | | | acid | | | |
| Example 19 | Tris | 1 [symbol] .0% | [symbol] .4% | DMMEA | 3.0% | 9. [symbol] % | Succinic | 10.0% | 32.1% | MEA |
| | | | | | | | acid | | | |
| Example 20 | Tris | 1 [symbol] .0% | 45.5% | DMMEA | 3.0% | 9. [symbol] % | Succinic | 12.0% | 3 [symbol] .4% | MEA |
| | | | | | | | acid | | | |
| Example 21 | Tris | 1 [symbol] .0% | 68.2% | DMMEA | 3.0% | 1 [symbol] . [symbol] % | [symbol] acid | 1.0% | 4.5% | MEA |
| Example 22 | Tris | 1 [symbol] .0% | 68.2% | DMMEA | 3.0% | 1 [symbol] .0% | [symbol] acid | 1.0% | 4. [symbol] % | MEA |
| Example 23 | Tris | 1 [symbol] .0% | 68.2% | DMMEA | 3.0% | 13. [symbol] % | Glutaric acid | 1.0% | 4.5% | MEA |
| Example 24 | Tris | 1 [symbol] .0% | 68.2% | DMMEA | 3.0% | 13. [symbol] % | [symbol] acid | 1.0% | 4.5% | MEA |
| Example 25 | Tris | 1 [symbol] .0% | 68.2% | DMMEA | 3.0% | 13. [symbol] % | Succinic | 1.0% | 4.5% | MEA |
| | | | | | | | acid | | | |
| Example 26 | Tris | [symbol] .0% | 25.0% | DMMEA | 5.0% | 41.7% | Succinic | 1.0% | [symbol] . [symbol] % | MEA |
| | | | | | | | acid | | | |
| Example 27 | Tris | 1 [symbol] .0% | 77.3% | DMMEA | 0. [symbol] % | 2.1% | Succinic | 1.0% | 5.2% | MEA |
| | | | | | | | acid | | | |
| Example 28 | Tris | 1 [symbol] .0% | 41.7% | DMMEA | 3.0% | [symbol] . [symbol] % | Succinic | 15.0% | 41.7% | MEA |
| | | | | | | | acid | | | |
| Example 29 | Tris | 1 [symbol] .0% | 38.5% | DMMEA | 3.0% | 7.7% | Succinic | 18.0% | 4 [symbol] .2% | MEA |
| | | | | | | | acid | | | |
| Example 30 | Tris | 1 [symbol] .0% | 70.1% | DMMEA | 3.0% | 14.0% | Succinic | 0.4% | 1.9% | MEA |
| | | | | | | | acid | | | |
| Example 31 | Tris | 1 [symbol] .0% | 6 [symbol] .8% | DMMEA | 0.5% | [symbol] . [symbol] % | Succinic | 5.0% | 21. [symbol] % | MEA |
| | | | | | | | acid | | | |
| Example 32 | Tris | 1 [symbol] .0% | 5 [symbol] . [symbol] % | DMMEA | 0.5% | 1. [symbol] % | Succinic | 8.0% | [symbol] 0. [symbol] % | MEA |
| | | | | | | | acid | | | |
| Example 33 | Tris | 1 [symbol] .0% | 44.4% | DMMEA | 1 [symbol] .0% | 44.4% | Succinic | 0.8% | 2.4% | MEA |
| | | | | | | | acid | | | |

| | (D) Primary amino alcohol | | | | | | | | |
|---|---|---|---|---|---|---|---|---|---|
| | (D1) MEA | | (D2) AEE | | | (D1) Others | | | (D) Content |
| | | Concentration in | | | Concentration in | | | Concentration in | Concentration in |
| | Content | solid content | Kind | Content | solid content | Kind | Content | solid content | solid content |
| Example 16 | 3.0% | 14.0% | | | | | | | 14.0% |
| Example 17 | 3.0% | 12.5% | | | | | | | 12.5% |
| Example 18 | 3.0% | 11.5% | | | | | | | 11.5% |
| Example 19 | 3.0% | 9.7% | | | | | | | 9.7% |
| Example 20 | 3.0% | 9.1% | | | | | | | 9.1% |
| Example 21 | 3.0% | 13.6% | | | | | | | 13.6% |
| Example 22 | 3.0% | 13.6% | | | | | | | 13.6% |
| Example 23 | 3.0% | 13.6% | | | | | | | 13.6% |
| Example 24 | 3.0% | 13.6% | | | | | | | 13.6% |
| Example 25 | 3.0% | 13.6% | | | | | | | 13.6% |
| Example 26 | 3.0% | [symbol] . [symbol] % | | | | | | | 2 [symbol] .0% |
| Example 27 | 3.0% | 15.5% | | | | | | | 15.5% |
| Example 28 | 3.0% | 8.3% | | | | | | | 8.1% |
| Example 29 | 3.0% | 7.7% | | | | | | | 7.7% |
| Example 30 | 3.0% | 14.0% | | | | | | | 14.0% |
| Example 31 | 3.0% | 12.8% | | | | | | | 12. [symbol] % |
| Example 32 | 3.0% | 11.3% | | | | | | | 11.3% |
| Example 33 | 3.0% | [symbol] . [symbol] % | | | | | | | 8. [symbol] % |

[symbol]

indicates data missing or illegible when filed

TABLE 4

| | Additive | | | | | | | | | | | | Evaluation | |
|---|---|---|---|---|---|---|---|---|---|---|---|---|---|---|
| | | | Concen- | | | | | | | | | | results | |
| (Continued | | | tration | | | | | | | pH | | pH | Cleaning | Surface |
| from | | | in solid | (A)/ | (A)/ | (B)/ | (A)/ | (B)/ | (D1)/ | adjusting | Water | after | perfor- | rough- |
| Table 3) | Kind | Content | content | (B) | (C) | (C) | (D) | (D) | (D2) | agent | Content | dilution | mance | ness |

| | | | | | | | | | | |
|---|---|---|---|---|---|---|---|---|---|---|
| Example 16 | [symbol] .00 | 30.00 | [symbol] .00 | 5.00 | 1.00 | H₂SO₄/KOH | Remainder | 12. [symbol] | C | B |
| Example 17 | [symbol] .00 | 5.00 | 1.00 | 5.00 | 1.00 | H₂SO₄/KOH | Remainder | 12. [symbol] | B | B |
| Example 18 | [symbol] .00 | [symbol] .00 | 0. [symbol] | 5.00 | 1.00 | H₂SO₄/KOH | Remainder | 12. [symbol] | B | B |
| Example 19 | [symbol] .00 | 1. [symbol] | 0. [symbol] | [symbol] .00 | 1.00 | H₂SO₄/KOH | Remainder | 11.7 | B | B |
| Example 20 | [symbol] .00 | 1.25 | 0. [symbol] | [symbol] .00 | 1.00 | H₂SO₄/KOH | Remainder | 11.8 | B | C |
| Example 21 | [symbol] .00 | 15.00 | 3.00 | 5.00 | 1.00 | H₂SO₄/KOH | Remainder | 12.2 | B | C |
| Example 22 | [symbol] .00 | 15.00 | 3.00 | [symbol] .00 | 1.00 | H₂SO₄/KOH | Remainder | 12.1 | B | B |
| Example 23 | [symbol] .00 | 15.00 | 3.00 | [symbol] .00 | 1.00 | H₂SO₄/KOH | Remainder | 12.0 | B | B |
| Example 24 | [symbol] .00 | 15.00 | 3.00 | 5.00 | 1.00 | H₂SO₄/KOH | Remainder | 12.1 | B | B |
| Example 25 | [symbol] .00 | 15.00 | 3.00 | 5.00 | 1.00 | H₂SO₄/KOH | Remainder | 12.1 | C | C |
| Example 26 | 0.60 | 3.00 | 5.00 | 1.00 | 1. [symbol] | H₂SO₄/KOH | Remainder | 10.6 | C | C |
| Example 27 | 37.50 | 15.00 | 0. [symbol] | 5.00 | 0.1 [symbol] | H₂SO₄/KOH | Remainder | 12.1 | C | C |
| Example 28 | [symbol] .00 | 1.00 | 0. [symbol] | 5.00 | 1.00 | H₂SO₄/KOH | Remainder | 11.5 | B | C |
| Example 29 | [symbol] .00 | 0. [symbol] | 0.17 | 5.00 | 1.00 | H₂SO₄/KOH | Remainder | 11.7 | C | C |
| Example 30 | [symbol] .00 | 17.50 | 7.50 | [symbol] .00 | 1.00 | H₂SO₄/KOH | Remainder | 12.4 | C | C |
| Example 31 | [symbol] 0.00 | [symbol] . [symbol] | 0.10 | [symbol] .00 | 0.17 | H₂SO₄/KOH | Remainder | 11. [symbol] | B | C |
| Example 32 | [symbol] 0.00 | 1. [symbol] | 0.0 [symbol] | 5.00 | 0.17 | H₂SO₄/KOH | Remainder | 11.9 | C | C |
| Example 33 | 1.00 | 18. [symbol] | 18.75 | 5.00 | 5.00 | H₂SO₄/KOH | Remainder | 12.1 | C | C |

[symbol]

indicates data missing or illegible when filed

TABLE 5

| | | | | | | | | | | (D) Primary |
|---|---|---|---|---|---|---|---|---|---|---|
| | (A) Compound (1) | | | (B) Tertiary amino | | | (C) Compound (2) | | | amino alcohol |
| | | | Concentration in | | | Concentration in | | | Concentration in | (D1) MEA |
| | Kind | Content | solid content | Kind | Content | solid content | Kind | Content | solid content | Kind |
| Example 34 | Tris | 15.0% | 66.7% | DMMEA | 3.0% | 13.3% | Succinate | 1.0% | 4.4% | MEA |
| | | | | | | | acid | | | |
| Example 35 | Tris | 15.0% | 60.0% | DMMEA | 3.0% | 12.0% | Succinate | 1.0% | 4.0% | MEA |
| | | | | | | | acid | | | |
| Example 36 | Tris | 15.0% | [symbol] . % | DMMEA | 3.0% | 13.3% | Succinate | 1.0% | 4.4% | |
| | | | | | | | acid | | | |
| Example 37 | Tris | 15.0% | 51.7% | DMMEA | 3.0% | 10.3% | Succinate | 1.0% | [symbol] .4% | MEA |
| | | | | | | | acid | | | |
| Example 38 | Tris | 15.0% | 51.7% | DMMEA | 3.0% | 10.3% | Succinate | 1.0% | [symbol] .4% | MEA |
| | | | | | | | acid | | | |
| Example 39 | Tris | 15.0% | [symbol] 7.9% | DMMEA | 3.0% | 13. [symbol] % | Succinate | 1.0% | 4.5% | MEA |
| | | | | | | | acid | | | |
| Example 40 | Tris | 15.0% | [symbol] .2% | DMMEA | 3.0% | 1 [symbol] . [symbol] % | Succinate | 1.0% | 4.3% | MEA |
| | | | | | | | acid | | | |
| Example 41 | Tris | 15.0% | [symbol] .8% | DMMEA | 3.0% | 12. [symbol] % | [symbol] | 1.0% | 4.3% | MEA |
| | | | | | | | acid | | | |
| Example 42 | Tris | 15.0% | 61.2% | DMMEA | 3.0% | 13.0% | Succinate | 1.0% | 4.1% | MEA |
| | | | | | | | acid | | | |
| Example 43 | Tris | 15.0% | 6 [symbol] .2% | DMMEA | 3.0% | 13.0% | Succinate | 2.0% | 8.7% | MEA |
| | | | | | | | acid 1% + | | | |
| | | | | | | | [symbol] acid 1% | | | |
| Example 44 | Tris | 15.0% | 65.2% | DMMEA | 3.0% | 1 [symbol] . [symbol] % | Succinate | 2.0% | [symbol] . [symbol] % | MEA |
| | | | | | | | acid 1% + | | | |
| | | | | | | | [symbol] acid 1% | | | |
| Example 45 | Tris | 1 [symbol] .0% | [symbol] . [symbol] % | DMMEA | 3.0% | 13. [symbol] % | Succinate | 1.0% | 4. [symbol] % | MEA |
| | | | | | | | acid | | | |
| Comparative | TMAE | 15.0% | 68.2% | DMMEA | 3.0% | [symbol] .9% | Succinate | 1.0% | 4.5% | MEA |
| Example 1 | | | | | | | acid | | | |
| Comparative | | | | DMMEA | 3.0% | | Succinate | 1.0% | 14. [symbol] % | MEA |
| Example 2 | | | | | | | acid | | | |
| Comparative | Tris | 15.0% | 78.9% | | | 14.3% | Succinate | 1.0% | [symbol] .3% | MEA |
| Example 3 | | | | | | | acid | | | |
| Comparative | Tris | 15.0% | 71.4% | DMMEA | 3.0% | 1 [symbol] .8% | | | | MEA |
| Example 4 | | | | | | | | | | |
| Comparative | Tris | 1 [symbol] .0% | 7 [symbol] . [symbol] % | DMMEA | 3.0% | | Succinate | 1.0% | [symbol] .3% | |
| Example 5 | | | | | | | acid | | | |

| | (D) Primary amino alcohol | | | | | | | | |
|---|---|---|---|---|---|---|---|---|---|
| | (D1) MEA | | (D2) AEE | | | (D1) Others | | | (D) Content |
| | | Concentration in | | | Concentration in | | | Concentration in | Concentration in |
| | Content | solid content | Kind | Content | solid content | Kind | Content | solid content | solid content |
| Example 34 | [symbol] . [symbol] % | 13.3% | AEE | 0. [symbol] % | 2. [symbol] % | | | | 15.6% |
| Example 35 | [symbol] . [symbol] % | 12.0% | | | | AMP | [symbol] .0% | 12.0% | 24.0% |
| Example 36 | | | AEE | 0. [symbol] % | 2.2% | AMP | [symbol] .0% | 13.3% | 15.6% |
| Example 37 | 10.0% | 34. [symbol] % | AEE | 0.0% | 0. [symbol] % | | | | 34.5% |
| Example 38 | 10.0% | 34. [symbol] % | AEE | 0.0% | 0.1% | | | | 34.5% |
| Example 39 | [symbol] . [symbol] % | 1 [symbol] . [symbol] % | AEE | 0.1% | 0.5% | | | | 14.0% |
| Example 40 | [symbol] . [symbol] % | 1 [symbol] .0% | AEE | 1.0% | 1.3% | | | | 17.4% |
| Example 41 | [symbol] . [symbol] % | 6.4% | AEE | 3.0% | 12.8% | | | | 19.1% |
| Example 42 | [symbol] . [symbol] % | 6.1% | AEE | 4.0% | 16.3% | | | | 22.4% |
| Example 43 | [symbol] . [symbol] % | 1 [symbol] .0% | | | | | | | 13.0% |
| Example 44 | [symbol] . [symbol] % | 13.0% | | | | | | | 13.0% |
| Example 45 | [symbol] . [symbol] % | 13.0% | | | | | | | 13. [symbol] % |
| Comparative | [symbol] . [symbol] % | 1 [symbol] .0% | | | | | | | 13.6% |
| Example 1 | | | | | | | | | |
| Comparative | [symbol] . [symbol] % | 42.9% | | | | | | | 12. [symbol] % |
| Example 2 | | | | | | | | | |
| Comparative | [symbol] . [symbol] % | 1 [symbol] . [symbol] % | | | | | | | 1 [symbol] .8% |
| Example 3 | | | | | | | | | |
| Comparative | [symbol] . [symbol] % | 14. [symbol] | | | | | | | 14. [symbol] % |
| Example 4 | | | | | | | | | |
| Comparative | | | | | | | | | |
| Example 5 | | | | | | | | | |

[symbol]

indicates data missing or illegible when filed

TABLE 6

| | Additive | | | | | | | | | | | | Evaluation | |
|---|---|---|---|---|---|---|---|---|---|---|---|---|---|---|
| | | | Concen- | | | | | | | | | | results | |
| (Continued | | | tration | | | | | | | pH | | pH | Cleaning | Surface |
| from | | | in solid | (A)/ | (A)/ | (B)/ | (A)/ | (B)/ | (D1)/ | adjusting | Water | after | perfor- | rough- |
| Table 5) | Kind | Content | content | (B) | (C) | (C) | (D) | (D) | (D2) | agent | Content | dilution | mance | ness |
| Example 34 | | | | [symbol] .00 | 15.00 | 3.00 | 4. [symbol] | 0. [symbol] | 6.00 | H₂SO₄/KOH | Remainder | 12.2 | A | A |
| Example 35 | | | | [symbol] .00 | 15.00 | 3.00 | 2. [symbol] | 0. [symbol] | | H₂SO₄/KOH | Remainder | 12.1 | A | B |
| Example 36 | | | | [symbol] .00 | 15.00 | 3.00 | 4. [symbol] | 0. [symbol] | | H₂SO₄/KOH | Remainder | 12.4 | B | A |
| Example 37 | | | | [symbol] .00 | 15.00 | 3.00 | 1.50 | 0. [symbol] | 1000.00 | H₂SO₄/KOH | Remainder | 12.1 | C | A |
| Example 38 | | | | [symbol] .00 | 15.00 | 3.00 | 1.50 | 0. [symbol] | [symbol] 00.00 | H₂SO₄/KOH | Remainder | 12.1 | B | A |
| Example 39 | | | | [symbol] .00 | 15.00 | 3.00 | 4. [symbol] 4 | 0. [symbol] | [symbol] 0.00 | H₂SO₄/KOH | Remainder | 12.1 | A | A |
| Example 40 | | | | [symbol] .00 | 15.00 | 3.00 | 3.75 | 0. [symbol] | [symbol] .00 | H₂SO₄/KOH | Remainder | 12.3 | A | A |
| Example 41 | | | | [symbol] .00 | 15.00 | 3.00 | 3.31 | 0. [symbol] | 0. [symbol] | H₂SO₄/KOH | Remainder | 12.1 | A | B |
| Example 42 | | | | [symbol] .00 | 15.00 | 3.00 | 2.71 | 0. [symbol] | 0.38 | H₂SO₄/KOH | Remainder | 12.3 | A | C |
| Example 43 | | | | [symbol] .00 | 7.50 | 1.50 | 5.00 | 1.00 | | H₂SO₄/KOH | Remainder | 12.1 | B | A |
| Example 44 | | | | [symbol] .00 | 7.50 | 1.50 | 5.00 | 1.00 | | H₂SO₄/KOH | Remainder | 12.1 | B | A |
| Example 45 | [symbol] X | 0.10% | 0. [symbol] % | [symbol] .00 | 15.00 | 3.00 | 5.00 | 1.00 | | H₂SO₄/KOH | Remainder | 12.4 | A | B |
| Comparative | | | | [symbol] .00 | 15.00 | 3.00 | 5.00 | 1.00 | | H₂SO₄/KOH | Remainder | 12.3 | E | C |
| Example 1 | | | | | | | | | | | | | | |
| Comparative | | | | | | 3.00 | | 1.00 | | H₂SO₄/KOH | Remainder | 10.3 | E | D |
| Example 2 | | | | | | | | | | | | | | |
| Comparative | | | | | 15.00 | | 5.00 | | | H₂SO₄/KOH | Remainder | 10.2 | D | E |
| Example 3 | | | | | | | | | | | | | | |
| Comparative | | | | [symbol] .00 | | | 5.00 | 1.00 | | H₂SO₄/KOH | Remainder | 12.2 | [symbol] | D |
| Example 4 | | | | | | | | | | | | | | |
| Comparative | | | | [symbol] .00 | 15.00 | 3.00 | | | | H₂SO₄/KOH | Remainder | 12.2 | D | E |
| Example 5 | | | | | | | | | | | | | | |

[symbol]

indicates data missing or illegible when filed

From the evaluation results, it was confirmed that in a case where the cleaning liquid according to the embodiment of the present invention is used, a desired effect is obtained.

From the comparison between Examples 1, 3, and 4, and Example 2, it was confirmed that in a case where at R¹, . . . , or R⁴ in Formula (1) is a hydroxyalkyl group, the effect is more excellent.

From the comparison between Examples 1 and 4, and Examples 2 and 3, it was confirmed that in a case where at least two of R¹, . . . , or R⁴ in Formula (1) is a hydroxyalkyl group, the effect is more excellent.

From the comparison between Examples 1 and Examples 2 to 4, it was confirmed that in a case where the compound represented by Formula (1) includes tris(2-hydroxyethyl)methylammonium hydroxide, the effect is more excellent.

From the comparison between Examples 1 and 10, and Example 11, it was confirmed that in a case where the tertiary amine is a secondary amino alcohol, the effect is more excellent.

From the comparison between Example 1 and Example 11, it was confirmed that in a case where the tertiary amine includes 2-(dimethylamino)ethanol, the effect is more excellent.

From the comparison between Examples 5 to 9 and 12 to 15, and Examples 26 and 27, it was confirmed that in a case where the mass ratio ((A)/(B)) of the content of the compound represented by Formula (1) to the content of the tertiary amine is 1.00 to 30.00, the effect is more excellent.

From the comparison between Examples 1 and 6 to 8, and Examples 5 and 9, it was confirmed that in a case where the mass ratio ((A)/(D)) of the content of the compound represented by Formula (1) to the content of the primary amino alcohol 1.50 to 7.00, the effect is more excellent.

From the comparison between Examples 1 and 13 to 14, and Examples 12 and 15, it was confirmed that in a case where the mass ratio ((B)/(D)) of the content of the tertiary amine to the content of the primary amino alcohol is 0.30 to 4.00, the effect is more excellent.

From the comparison between Examples 34 to 36, and Example 1, it was confirmed that in a case where the primary amino alcohol has at least two selected from the group consisting of an amino alcohol having a primary amino group and an amino alcohol having a secondary amino group, the effect is more excellent.

From the comparison between Examples 34 and Examples 35 to 36, it was confirmed that in a case where the primary amino alcohol includes 2-aminoethanol and 2-(2-aminoethylamino)ethanol, the effect is more excellent.

From the comparison between Examples 34 and 38 to 41, and Examples 38 and 41, it was confirmed that in a case where the primary amino alcohol includes 2-aminoethanol and 2-(2-aminoethylamino)ethanol and the mass ratio of the content of 2-aminoethanol to the content of 2-(2-aminoethylamino)ethanol is 0.50 to 900.00, the effect is more excellent.

In the evaluation test for the cleaning performance, a wafer having a metal film consisting of copper on the surface was subjected to a CMP treatment, and then the surface of the polished wafer was subjected to a buffing treatment. In the buffing treatment, a sample of each diluted cleaning liquid adjusted to room temperature (23° C.) was used as a composition for a buffing treatment. In addition, a buffing treatment was carried out under the conditions of a polishing pressure of 2.0 psi, a supply rate of the composition for a buffing treatment: 0.28 mL/(min·cm²), and a polishing time of 60 seconds, using the polishing device used in the CMP treatment.

Then, the wafer that had been subjected to a buffing treatment was cleaned over 30 seconds using a sample of each diluted cleaning liquid adjusted to room temperature (23° C.) and then subjected to a drying treatment.

As a result of evaluating the corrosion prevention performance of the cleaning liquid on a polished surface of the obtained wafer according to the evaluation test method of [Evaluation of cleaning performance] described above, it was confirmed that the same evaluation results as those of the cleaning liquid of each of Examples above are shown.

What is claimed is:

1. A cleaning liquid for a semiconductor substrate, which is used for cleaning a semiconductor substrate, the cleaning liquid comprising:
a compound represented by Formula (1);
a compound represented by Formula (2);
a primary amino alcohol having a primary amino group or a secondary amino group;
a tertiary amine; and
a solvent, 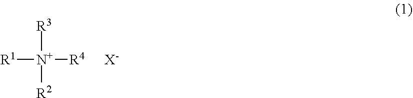
in Formula (1), R¹ to R⁴ each independently represent a hydrocarbon group which may have a substituent, and
X⁻ represents an anion,
provided that a case where all of R¹ to R⁴ represent a methyl group is excluded, 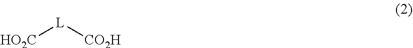
in Formula (2), L represents a single bond or a divalent linking group.

2. The cleaning liquid for a semiconductor substrate according to claim 1,
wherein at R¹, . . . , or R⁴ in Formula (1) is a hydroxyalkyl group.

3. The cleaning liquid for a semiconductor substrate according to claim 1,
wherein at least two of R¹, . . . , or R⁴ in Formula (1) is a hydroxyalkyl group.

4. The cleaning liquid for a semiconductor substrate according to claim 1,
wherein the compound represented by Formula (1) includes tris(2-hydroxyethyl)methylammonium hydroxide.

5. The cleaning liquid for a semiconductor substrate according to claim 1,
wherein a content of the compound represented by Formula (1) is 20.0% to 80.0% by mass with respect to a total mass of components of the cleaning liquid for a semiconductor substrate excluding the solvent.

6. The cleaning liquid for a semiconductor substrate according to claim 1,
wherein the tertiary amine is a secondary amino alcohol having a tertiary amino group.

7. The cleaning liquid for a semiconductor substrate according to claim 1,
wherein the tertiary amine includes 2-(dimethylamino)ethanol.

8. The cleaning liquid for a semiconductor substrate according to claim 1,
wherein a content of the tertiary amine is 3.0% to 35.0% by mass with respect to a total mass of components of the cleaning liquid for a semiconductor substrate excluding the solvent.

9. The cleaning liquid for a semiconductor substrate according to claim 1,
wherein a content of the compound represented by Formula (2) is 2.0% to 50.0% by mass with respect to a total mass of components of the cleaning liquid for a semiconductor substrate excluding the solvent.

10. The cleaning liquid for a semiconductor substrate according to claim 1,
wherein a mass ratio of a content of the compound represented by Formula (1) to a content of the tertiary amine is 1.00 to 30.00.

11. The cleaning liquid for a semiconductor substrate according to claim 1,
wherein a mass ratio of a content of the compound represented by Formula (1) to a content of the primary amino alcohol is 1.50 to 7.00.

12. The cleaning liquid for a semiconductor substrate according to claim 1,
wherein a mass ratio of a content of the tertiary amine to a content of the primary amino alcohol is 0.30 to 4.00.

13. The cleaning liquid for a semiconductor substrate according to claim 1,
wherein a ratio of the number of carbon atoms of the primary amino alcohol to the number of nitrogen atoms of the primary amino alcohol is 2 to 5.

14. The cleaning liquid for a semiconductor substrate according to claim 1,
wherein the primary amino alcohol includes at least two selected from the group consisting of an amino alcohol having a primary amino group and an amino alcohol having a secondary amino group.

15. The cleaning liquid for a semiconductor substrate according to claim 1,
wherein the primary amino alcohol includes at least one selected from the group consisting of 2-aminoethanol and 2-(2-aminoethylamino)ethanol.

16. The cleaning liquid for a semiconductor substrate according to claim 1,
wherein the primary amino alcohol includes 2-aminoethanol and 2-(2-aminoethylamino)ethanol.

17. The cleaning liquid for a semiconductor substrate according to claim 1,
wherein the primary amino alcohol includes 2-aminoethanol and 2-(2-aminoethylamino)ethanol, and
a mass ratio of a content of the 2-aminoethanol to a content of the 2-(2-aminoethylamino)ethanol is 0.50 to 900.00.

18. The cleaning liquid for a semiconductor substrate according to claim 1,
wherein the solvent includes water.

19. The cleaning liquid for a semiconductor substrate according to claim 1,
wherein a pH of the cleaning liquid for a semiconductor substrate is 8.0 to 13.0.

20. The cleaning liquid for a semiconductor substrate according to claim 1,
wherein the cleaning liquid for a semiconductor substrate is used for applying a cleaning liquid to a semiconductor substrate that has been subjected to a chemical mechanical polishing treatment to carry out cleaning.
